(19) United States
(12) Patent Application Publication
(10) Pub. No.: US 2024/0422911 A1
(43) Pub. Date: Dec. 19, 2024

(54) ELECTRONIC DEVICE INCLUDING SUPPORTING STRUCTURE FOR PRINTED CIRCUIT BOARD

(71) Applicant: SAMSUNG ELECTRONICS CO., LTD., Suwon-si (KR)

(72) Inventors: Dohyeong PARK, Suwon-si (KR); Junghoon PARK, Suwon-si (KR)

(73) Assignee: SAMSUNG ELECTRONICS CO., LTD., Suwon-si (KR)

(21) Appl. No.: 18/627,096

(22) Filed: Apr. 4, 2024

Related U.S. Application Data
(63) Continuation of application No. PCT/KR24/03360, filed on Mar. 18, 2024.

(30) Foreign Application Priority Data
Jun. 14, 2023 (KR) 10-2023-0076464
Jul. 25, 2023 (KR) 10-2023-0096905

(51) Int. Cl. H05K 1/14; H05K 1/18; H05K 5/00

(52) U.S. Cl. CPC H05K 1/144; H05K 1/181; H05K 5/003; H05K 2201/10378

(57) ABSTRACT

According to an embodiment, an electronic device includes a first printed circuit board and a second printed circuit board, facing the first printed circuit board, disposed over the first printed circuit board. The electronic device includes a first support member disposed on a first surface of the first printed circuit board. The electronic device includes a second support member, disposed on a second surface of the second printed circuit board, facing the first printed circuit board and configured to come into contact with the first support member by an external force applied to the electronic device. The electronic device includes an interposer between the first printed circuit board and the second printed circuit board, surrounding an area between the first surface and the second surface.

### CROSS-REFERENCE TO RELATED APPLICATIONS

This application is a by-pass continuation application of International Application No. PCT/KR2024/003360, filed on Mar. 18, 2024, which is based on and claims priority to Korean Patent Application Nos. 10-2023-0076474, filed on Jun. 14, 2023, and 10-2023-0096905, filed on Jul. 25, 2023, in the Korean Intellectual Property Office, the disclosures of which are incorporated by reference herein their entireties.

### BACKGROUND

### 1. Field

The disclosure relates to an electronic device including a supporting structure that supports a printed circuit board.

### 2. Description of Related Art

A small electronic device (such as a smartphone and a tablet personal computer (PC)) may include a printed circuit board (PCB) (on which electronic components are mounted in the electronic device) to implement various functions of the electronic device. In order to reduce damage to electronic components by external impact, the electronic device may include a supporting structure that supports the printed circuit board.

The above-described information may be provided as related art for the purpose of helping to understand the disclosure. No claim or determination is raised as to whether any of the above-described information may be applied as related art related to the disclosure.

### SUMMARY

An electronic device according to an embodiment may comprise a first printed circuit board. The electronic device may comprise a second printed circuit board, disposed over the first printed circuit board. The electronic device may comprise a first support member disposed on a first surface of the first printed circuit board. The electronic device may comprise a second support member disposed on a second surface of the second printed circuit board. The second support member may face the first printed circuit board. The second support member may space apart from the first support member. The second support member may configure to come into contact with the first support member by an external force applied to the electronic device. The electronic device may comprise an interposer, between the first printed circuit board and the second printed circuit board, surrounding an area between the first surface and the second surface.

An electronic device according to an embodiment may comprise a first printed circuit board. The electronic device may comprise a second printed circuit board facing the first printed circuit board, disposed on the first printed circuit board. The electronic device may comprise a first support member disposed on a first surface of the first printed circuit board facing the second printed circuit board. The electronic device may comprise a second support member disposed on a second surface of the second printed circuit board facing the first printed circuit board, and facing the first support member and spaced apart from the first support member so as to be contactable with the first support member. The electronic device may comprise a first set of electronic components disposed on the first surface and a second set of electronic components disposed on the second surface. The electronic device may comprise an interposer between the first printed circuit board and the second printed circuit board surrounding the space between the first surface and the second surface. A sum of a length of the first support member extending from the first surface toward the second surface and a length of the second support member extending from the second surface toward the first surface may be greater than a sum of a length of one electronic component among the first set of electronic components extending from the first surface toward the second surface and a length of another electronic component among the second set of electronic components facing at least portion of the one electronic component extending from the second surface toward the first surface.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a block diagram of an electronic device in a network environment according to an embodiment;

FIG. 2 is a diagram illustrating an electronic device according to an embodiment;

FIG. 3 is an exploded perspective view of an electronic device according to an embodiment;

FIG. 4A is a partially exploded perspective view of an exemplary electronic device;

FIG. 4B is a partial cross-sectional view of an exemplary electronic device;

FIG. 5A illustrates a portion of an exemplary electronic device in a first state;

FIG. 5B illustrates a portion of an exemplary electronic device in a second state;

FIGS. 6A, 6B, and 6C are partial cross-sectional views of an exemplary electronic device;

FIG. 7 is a partial cross-sectional view of an exemplary electronic device;

FIG. 8A illustrates a portion of an exemplary electronic device in which a plurality of support members is disposed;

FIG. 8B is a circuit diagram for detecting an abnormal state of an electronic device;

FIGS. 9A and 9B are flow charts illustrating an operation of a processor of an exemplary electronic device; and

FIG. 10 is a flow chart illustrating an operation of a processor of an exemplary electronic device.

### DETAILED DESCRIPTION

Hereinafter, with reference to a drawing, an embodiment of the disclosure will be described in detail so that those having ordinary knowledge in the art may easily implement the embodiment. However, the disclosure may be implemented in several different forms and is not limited to the embodiment described herein. In relation to a description of a drawing, same or similar reference number may be used for an identical or similar component. In addition, in the drawing and a related description, a description of a well-known function and a configuration may be omitted for clarity and brevity.

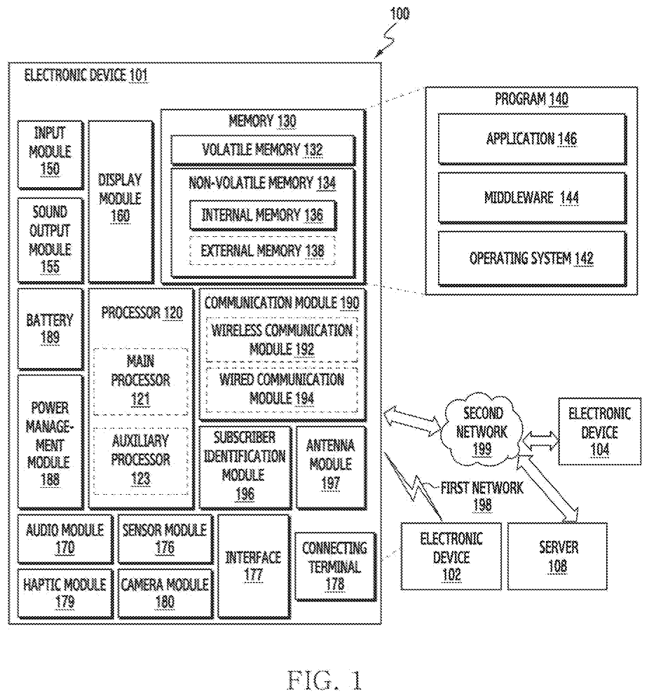

FIG. 1 is a block diagram illustrating an electronic device 101 in a network environment 100 according to various embodiments.

Referring to FIG. 1, the electronic device 101 in the network environment 100 may communicate with an electronic device 102 via a first network 198 (e.g., a short-range wireless communication network), or at least one of an electronic device 104 or a server 108 via a second network 199 (e.g., a long-range wireless communication network). According to an embodiment, the electronic device 101 may communicate with the electronic device 104 via the server 108. According to an embodiment, the electronic device 101 may include a processor 120, memory 130, an input module 150, a sound output module 155, a display module 160, an audio module 170, a sensor module 176, an interface 177, a connecting terminal 178, a haptic module 179, a camera module 180, a power management module 188, a battery 189, a communication module 190, a subscriber identification module (SIM) 196, or an antenna module 197. In some embodiments, at least one of the components (e.g., the connecting terminal 178) may be omitted from the electronic device 101, or one or more other components may be added in the electronic device 101. In some embodiments, some of the components (e.g., the sensor module 176, the camera module 180, or the antenna module 197) may be implemented as a single component (e.g., the display module 160). In some embodiments, the processor 120 may correspond to at least one processor (e.g., two or more processors).

The processor 120 may execute, for example, software (e.g., a program 140) to control at least one other component (e.g., a hardware or software component) of the electronic device 101 coupled with the processor 120, and may perform various data processing or computation. According to an embodiment, as at least part of the data processing or computation, the processor 120 may store a command or data received from another component (e.g., the sensor module 176 or the communication module 190) in volatile memory 132, process the command or the data stored in the volatile memory 132, and store resulting data in non-volatile memory 134. According to an embodiment, the processor 120 may include a main processor 121 (e.g., a central processing unit (CPU) or an application processor (AP)), or an auxiliary processor 123 (e.g., a graphics processing unit (GPU), a neural processing unit (NPU), an image signal processor (ISP), a sensor hub processor, or a communication processor (CP)) that is operable independently from, or in conjunction with, the main processor 121. For example, when the electronic device 101 includes the main processor 121 and the auxiliary processor 123, the auxiliary processor 123 may be adapted to consume less power than the main processor 121, or to be specific to a specified function. The auxiliary processor 123 may be implemented as separate from, or as part of the main processor 121.

The auxiliary processor 123 may control at least some of functions or states related to at least one component (e.g., the display module 160, the sensor module 176, or the communication module 190) among the components of the electronic device 101, instead of the main processor 121 while the main processor 121 is in an inactive (e.g., sleep) state, or together with the main processor 121 while the main processor 121 is in an active state (e.g., executing an application). According to an embodiment, the auxiliary processor 123 (e.g., an image signal processor or a communication processor) may be implemented as part of another component (e.g., the camera module 180 or the communication module 190) functionally related to the auxiliary processor 123. According to an embodiment, the auxiliary processor 123 (e.g., the neural processing unit) may include a hardware structure specified for artificial intelligence model processing. An artificial intelligence model may be generated by machine learning. Such learning may be performed, e.g., by the electronic device 101 where the artificial intelligence is performed or via a separate server (e.g., the server 108). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted Boltzmann machine (RBM), a deep belief network (DBN), a bidirectional recurrent deep neural network (BRDNN), deep Q-network or a combination of two or more thereof but is not limited thereto. The artificial intelligence model may, additionally or alternatively, include a software structure other than the hardware structure.

The memory 130 may store various data used by at least one component (e.g., the processor 120 or the sensor module 176) of the electronic device 101. The various data may include, for example, software (e.g., the program 140) and input data or output data for a command related thereto. The memory 130 may include the volatile memory 132 or the non-volatile memory 134.

The program 140 may be stored in the memory 130 as software, and may include, for example, an operating system (OS) 142, middleware 144, or an application 146.

The input module 150 may receive a command or data to be used by another component (e.g., the processor 120) of the electronic device 101, from the outside (e.g., a user) of the electronic device 101. The input module 150 may include, for example, a microphone, a mouse, a keyboard, a key (e.g., a button), or a digital pen (e.g., a stylus pen).

The sound output module 155 may output sound signals to the outside of the electronic device 101. The sound output module 155 may include, for example, a speaker or a receiver. The speaker may be used for general purposes, such as playing multimedia or playing record. The receiver may be used for receiving incoming calls. According to an embodiment, the receiver may be implemented as separate from, or as part of the speaker.

The display module 160 may visually provide information to the outside (e.g., a user) of the electronic device 101. The display module 160 may include, for example, a display, a hologram device, or a projector and control circuitry to control a corresponding one of the display, hologram device, and projector. According to an embodiment, the display module 160 may include a touch sensor adapted to detect a touch, or a pressure sensor adapted to measure the intensity of force incurred by the touch.

The audio module 170 may convert a sound into an electrical signal and vice versa. According to an embodiment, the audio module 170 may obtain the sound via the input module 150, or output the sound via the sound output module 155 or a headphone of an external electronic device (e.g., an electronic device 102) directly (e.g., wiredly) or wirelessly coupled with the electronic device 101.

The sensor module 176 may detect an operational state (e.g., power or temperature) of the electronic device 101 or an environmental state (e.g., a state of a user) external to the electronic device 101, and then generate an electrical signal or data value corresponding to the detected state. According to an embodiment, the sensor module 176 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the electronic device 102) directly (e.g., wiredly) or wirelessly. According to an embodiment, the interface 177 may include, for example, a high definition multimedia interface (HDMI), a universal serial bus (USB) interface, a secure digital (SD) card interface, or an audio interface.

A connecting terminal 178 may include a connector via which the electronic device 101 may be physically connected with the external electronic device (e.g., the electronic device 102). According to an embodiment, the connecting terminal 178 may include, for example, a HDMI connector, a USB connector, a SD card connector, or an audio connector (e.g., a headphone connector).

The haptic module 179 may convert an electrical signal into a mechanical stimulus (e.g., a vibration or a movement) or electrical stimulus which may be recognized by a user via his tactile sensation or kinesthetic sensation. According to an embodiment, the haptic module 179 may include, for example, a motor, a piezoelectric element, or an electric stimulator.

The camera module 180 may capture a still image or moving images. According to an embodiment, the camera module 180 may include one or more lenses, image sensors, image signal processors, or flashes.

The power management module 188 may manage power supplied to the electronic device 101. According to an embodiment, the power management module 188 may be implemented as at least part of, for example, a power management integrated circuit (PMIC).

The battery 189 may supply power to at least one component of the electronic device 101. According to an embodiment, the battery 189 may include, for example, a primary cell which is not rechargeable, a secondary cell which is rechargeable, or a fuel cell.

The communication module 190 may support establishing a direct (e.g., wired) communication channel or a wireless communication channel between the electronic device 101 and the external electronic device (e.g., the electronic device 102, the electronic device 104, or the server 108) and performing communication via the established communication channel. The communication module 190 may include one or more communication processors that are operable independently from the processor 120 (e.g., the application processor (AP)) and supports a direct (e.g., wired) communication or a wireless communication. According to an embodiment, the communication module 190 may include a wireless communication module 192 (e.g., a cellular communication module, a short-range wireless communication module, or a global navigation satellite system (GNSS) communication module) or a wired communication module 194 (e.g., a local area network (LAN) communication module or a power line communication (PLC) module). A corresponding one of these communication modules may communicate with the external electronic device via the first network 198 (e.g., a short-range communication network, such as Bluetooth™, wireless-fidelity (Wi-Fi) direct, or infrared data association (IrDA)) or the second network 199 (e.g., a long-range communication network, such as a legacy cellular network, a 5G network, a next-generation communication network, the Internet, or a computer network (e.g., LAN or wide area network (WAN)). These various types of communication modules may be implemented as a single component (e.g., a single chip), or may be implemented as multi components (e.g., multi chips) separate from each other. The wireless communication module 192 may identify and authenticate the electronic device 101 in a communication network, such as the first network 198 or the second network 199, using subscriber information (e.g., international mobile subscriber identity (IMSI)) stored in the subscriber identification module 196.

The wireless communication module 192 may support a 5G network, after a 4G network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 192 may support a high-frequency band (e.g., the mmWave band) to achieve, e.g., a high data transmission rate. The wireless communication module 192 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The wireless communication module 192 may support various requirements specified in the electronic device 101, an external electronic device (e.g., the electronic device 104), or a network system (e.g., the second network 199). According to an embodiment, the wireless communication module 192 may support a peak data rate (e.g., 20 Gbps or more) for implementing eMBB, loss coverage (e.g., 164 dB or less) for implementing mMTC, or U-plane latency (e.g., 0.5 ms or less for each of downlink (DL) and uplink (UL), or a round trip of 1 ms or less) for implementing URLLC.

The antenna module 197 may transmit or receive a signal or power to or from the outside (e.g., the external electronic device) of the electronic device 101. According to an embodiment, the antenna module 197 may include an antenna including a radiating element composed of a conductive material or a conductive pattern formed in or on a substrate (e.g., a printed circuit board (PCB)). According to an embodiment, the antenna module 197 may include a plurality of antennas (e.g., array antennas). In such a case, at least one antenna appropriate for a communication scheme used in the communication network, such as the first network 198 or the second network 199, may be selected, for example, by the communication module 190 (e.g., the wireless communication module 192) from the plurality of antennas. The signal or the power may then be transmitted or received between the communication module 190 and the external electronic device via the selected at least one antenna. According to an embodiment, another component (e.g., a radio frequency integrated circuit (RFIC)) other than the radiating element may be additionally formed as part of the antenna module 197.

According to various embodiments, the antenna module 197 may form an mmWave antenna module. According to an embodiment, the mmWave antenna module may include a printed circuit board, a RFIC disposed on a first surface (e.g., the bottom surface) of the printed circuit board, or adjacent to the first surface and capable of supporting a designated high-frequency band (e.g., the mmWave band), and a plurality of antennas (e.g., array antennas) disposed on a second surface (e.g., the top or a side surface) of the printed circuit board, or adjacent to the second surface and capable of transmitting or receiving signals of the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, commands or data may be transmitted or received between the electronic device 101 and the external electronic device 104 via the server 108 coupled with the second network 199. Each of the electronic devices 102 or 104 may be a device of a same type as, or a different type, from the electronic device 101. According to an embodiment, all or some of operations to be executed at the electronic device 101 may be executed at one or more of the external electronic devices 102, 104, or 108. For example, if the electronic device 101 should perform a function or a service automatically, or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 101. The electronic device 101 may provide the outcome, with or without further processing of the outcome, as at least part of a reply to the request. To that end, a cloud computing, distributed computing, mobile edge computing (MEC), or client-server computing technology may be used, for example. The electronic device 101 may provide ultra low-latency services using, e.g., distributed computing or mobile edge computing. In another embodiment, the external electronic device 104 may include an internet-of-things (IoT) device. The server 108 may be an intelligent server using machine learning and/or a neural network. According to an embodiment, the external electronic device 104 or the server 108 may be included in the second network 199. The electronic device 101 may be applied to intelligent services (e.g., smart home, smart city, smart car, or healthcare) based on 5G communication technology or IoT-related technology.

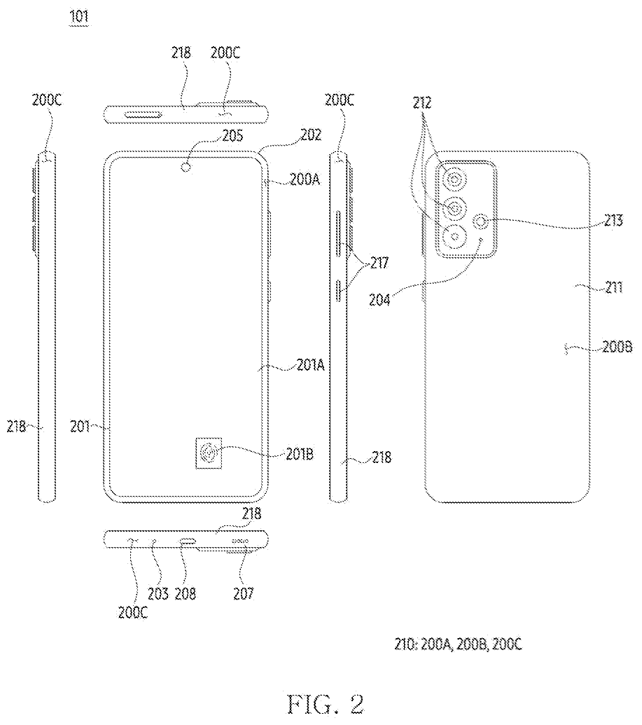

FIG. 2 is a diagram illustrating an electronic device according to an embodiment.

Referring to FIG. 2, an electronic device 101 according to an embodiment may include a housing 210 forming an exterior of the electronic device 101. For example, the housing 210 may include a front surface 200A, a rear surface 200B, and a side surface 200C surrounding a space between the front surface 200A and the rear surface 200B. According to an embodiment, the housing 210 may refer to a structure forming at least a portion of the front surface 200A, the rear surface 200B, and/or the side surface 200C.

The electronic device 101 according to an embodiment may include a substantially transparent front plate 202. According to an embodiment, the front plate 202 may form at least a portion of the front surface 200A. According to an embodiment, the front plate 202 may include, for example, a glass plate including various coating layers or a polymer plate, but embodiments of the disclosure are not limited thereto.

The electronic device 101 according to an embodiment may include a substantially opaque rear plate 211. According to an embodiment, the rear plate 211 may form at least a portion of the rear surface 200B. According to an embodiment, the rear plate 211 may be formed of coated or colored glass, ceramic, polymer, metal (e.g., aluminum, stainless steel (STS), or magnesium), or a combination of at least two of the above materials.

The electronic device 101 according to an embodiment may include a side structure (or side member) 218. According to an embodiment, the side structure 218 may be coupled to the front plate 202 and/or the rear plate 211 to form at least a portion of the side surface 200C of the electronic device 101. For example, the side structure 218 may form all of the side surface 200C of the electronic device 101. For another example, the side structure 218 may form the side surface 200C of the electronic device 101 together with the front plate 202 and/or the rear plate 211.

According to an embodiment, in the case that the side surface 200C of the electronic device 101 is partially formed by the front plate 202 and/or the rear plate 211, the front plate 202 and/or the rear plate 211 may include a region that is bent from its periphery toward the rear plate 211 and/or the front plate 202 and seamlessly extends. The extended region of the front plate 202 and/or the rear plate 211 may be positioned at both ends of, for example, a long edge of the electronic device 101, but embodiments of the disclosure are not limited to the above-described examples.

According to an embodiment, the side structure 218 may include a metal or a polymer. According to an embodiment, the rear plate 211 and the side structure 218 may be integrally formed and may include the same material (e.g., a metal material such as aluminum), but embodiments of the disclosure are not limited thereto. For example, the rear plate 211 and the side structure 218 may be formed in separate configurations and/or may include different materials.

According to an embodiment, the electronic device 101 may include at least one of a display 201, an audio module 203, 204 and 207, a sensor module, a camera module 205, 212, 213, a key input device 217, a light emitting device, and/or a connector hole 208. According to another embodiment, the electronic device 101 may omit at least one of the components (e.g., a key input device 217 or a light emitting device), or may further include another component.

According to an embodiment, the display 201 may be visually exposed through a substantial portion of the front plate 202. For example, at least a portion of the display 201 may be visible through the front plate 202 forming the front surface 200A. According to an embodiment, the display 201 may be disposed on the second surface of the front plate 202.

According to an embodiment, the appearance of the display 201 may be formed substantially the same as the appearance of the front plate 202 adjacent to the display 201. According to an embodiment, in order to expand the area in which the display 201 is visually exposed, the distance between the outside of the display 201 and the outside of the front plate 202 may be formed to be generally the same.

According to an embodiment, the display 201 (or the front surface 200A of the electronic device 101) may include a screen display area 201A. According to an embodiment, the display 201 may provide visual information to a user through the screen display area 201A. In the illustrated embodiment, when the front surface 200A is viewed from the front, it is illustrated that the screen display area 201A is spaced apart from the outside of the front surface 200A and is positioned inside the front surface 200A, but embodiments of the disclosure are not limited thereto. In another embodiment, when the front surface 200A is viewed from the front, at least a portion of the periphery of the screen display area 201A may substantially coincide with the periphery of the front surface 200A (or the front plate 202).

According to an embodiment, the screen display area 201A may include a sensing area 201B configured to obtain biometric information of a user. Here, the meaning of “the screen display area 201A including the sensing area 201B” may be understood to mean that at least a portion of the sensing area 201B may be overlapped on the screen display area 201A. For example, the sensing area 201B, like other areas of the screen display area 201A, may refer to an area in which visual information may be displayed by the display 201 and additionally biometric information (e.g., fingerprint) of a user may be obtained. In another embodiment, the sensing area 201B may be formed in the key input device 217.

According to an embodiment, the display 201 may include an area in which the first camera module 205 is positioned. According to an embodiment, an opening may be formed in the area of the display 201, and the first camera module 205 (e.g., a punch hole camera) may be at least partially disposed in the opening to face the front surface 200A. In such a case, the screen display area 201A may surround at least a portion of the periphery of the opening. According to an embodiment, the first camera module 205 (e.g., an under display camera (UDC)) may be disposed under the display 201 to overlap the area of the display 201. In this case, the display 201 may provide visual information to the user through the area, and additionally, the first camera module 205 may obtain an image corresponding to a direction facing the front surface 200A through the area of the display 201.

According to an embodiment, the display 201 may be coupled to or disposed adjacent to a touch sensing circuit, a pressure sensor capable of measuring the intensity (e.g., pressure) of the touch, and/or a digitizer that detects a magnetic field type stylus pen.

According to an embodiment, the audio modules 203, 204 and 207 may include microphone holes 203 and 204, and a speaker hole 207.

According to an embodiment, the microphone holes 203 and 204 may include a first microphone hole 203 formed in a partial area of the side surface 200C and a second microphone hole 204 formed in a partial area of the rear surface 200B. A microphone for obtaining an external sound may be disposed inside the microphone holes 203 and 204. The microphone may include a plurality of microphones to detect the direction of sound.

According to an embodiment, the second microphone hole 204 formed in a partial area of the rear surface 200B may be disposed adjacent to the camera modules 205, 212 and 213. For example, the second microphone hole 204 may obtain sound according to operations of the camera modules 205, 212, and 213. However, embodiments of the disclosure are not limited thereto.

According to an embodiment, the speaker hole 207 may include an external speaker hole 207 and a receiver hole for a call. The external speaker hole 207 may be formed on a portion of the side surface 200C of the electronic device 101. According to an embodiment, the external speaker hole 207 may be implemented as a single hole together with the microphone hole 203. According to an embodiment, a receiver hole for a call may be formed on another portion of the side surface 200C. For example, the receiver hole for a call may be formed on the opposite side of the external speaker hole 207 on the side surface 200C. For example, with respect to the illustration of FIG. 2, the external speaker hole 207 may be formed on the side surface 200C corresponding to the lower end of the electronic device 101, and the receiver hole for a call may be formed on the side surface 200C corresponding to the upper end of the electronic device 101. However, embodiments of the disclosure are not limited thereto, and according to an embodiment, the receiver hole for a call may be formed at a position other than the side surface 200C. For example, the receiver hole for a call may be formed by a space spaced apart between the front plate 202 (or display 201) and the side bezel structure 218.

According to an embodiment, the electronic device 101 may include at least one speaker configured to output sound to the outside of the housing 210 through an external speaker hole 207 and/or a receiver hole for a call.

According to an embodiment, the sensor module may generate an electrical signal or data value corresponding to an internal operating state or an external environmental state of the electronic device 101. For example, the sensor module may include at least one of a proximity sensor, an HRM sensor, a fingerprint sensor, a gesture sensor, a gyro sensor, a pressure sensor, a magnetic sensor, an acceleration sensor, a grip sensor, a color sensor, an infrared (IR) sensor, a biometric sensor, a temperature sensor, a humidity sensor, and an illumination sensor.

According to an embodiment, the camera modules 205, 212 and 213 may include a first camera module 205 disposed to face the front surface 200A of the electronic device 101, a second camera module 212 disposed to face the rear surface 200B, and a flash 213.

According to an embodiment, the second camera module 212 may include a plurality of cameras (e.g., a dual camera, a triple camera, or a quad camera). However, the second camera module 212 is not necessarily limited to including a plurality of cameras, and may include one camera.

According to an embodiment, the first camera module 205 and the second camera module 212 may include one or a plurality of lenses, an image sensor, and/or an image signal processor.

According to an embodiment, the flash 213 may include, for example, a light emitting diode or a xenon lamp. According to an embodiment, two or more lenses (infrared camera, wide-angle and telephoto lens) and image sensors may be disposed on one side of the electronic device 101.

According to an embodiment, the key input device 217 (e.g., an input module 150 of FIG. 1) may be disposed on the side surface 200C of the electronic device 101. According to an embodiment, the electronic device 101 may not include some or all of the key input devices 217, and the key input device 217 not included therein may be implemented on the display 201 in another form such as a soft key.

According to an embodiment, the connector hole 208 may be formed on the side surface 200C of the electronic device 101 to accommodate the connector of the external device. A connection terminal electrically connected to the connector of the external device may be disposed in the connector hole 208. The electronic device 101 according to an embodiment may include an interface module for processing electrical signals transmitted and received through the connection terminal.

According to an embodiment, the electronic device 101 may include a light emitting device. For example, the light emitting device may be disposed on the front surface 200A of the housing 210. The light emitting device may provide state information of the electronic device 101 in a form of light. In another embodiment, the light emitting device may provide a light source when the first camera module 205 is operated. For example, the light emitting device may include an LED, an IR LED, and/or a xenon lamp.

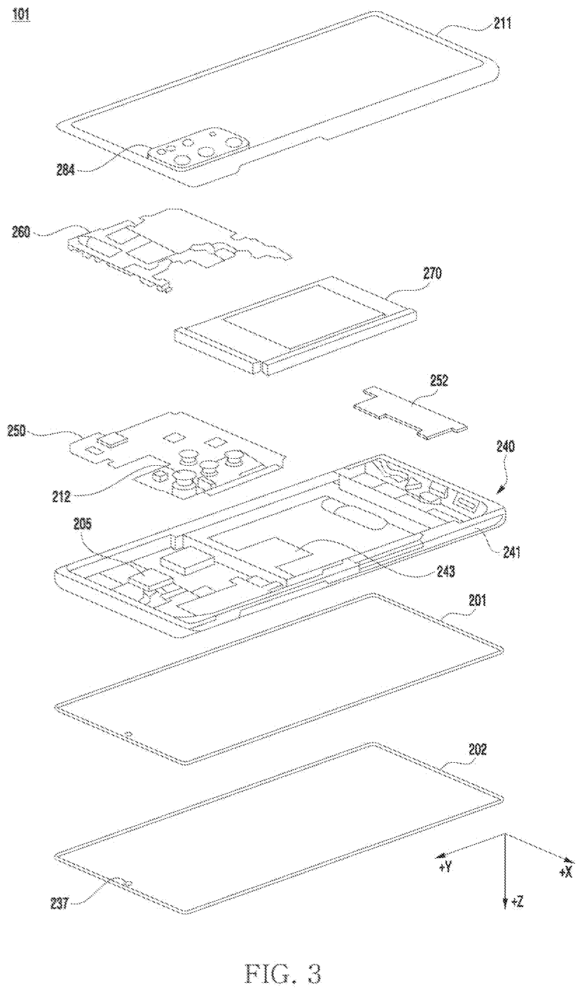

FIG. 3 is an exploded perspective view of an electronic device according to an embodiment.

Hereinafter, overlapping descriptions of components having the same reference numerals as those of the above-described components will be omitted.

Referring to FIG. 3, the electronic device 101 according to an embodiment may include a frame structure 240, a first printed circuit board 250, a second printed circuit board 252, a cover plate 260, and a battery 270.

According to an embodiment, the frame structure 240 may include a sidewall 241 forming an exterior (e.g., the side surface 200C of FIG. 2) of the electronic device 101 and a support portion 243 extending inward from the sidewall 241. According to an embodiment, the frame structure 240 may be disposed between the display 201 and the rear plate 211. According to an embodiment, the sidewall 241 of the frame structure 240 may surround a space between the rear plate 211 and the front plate 202 (and/or the display 201), and the support portion 243 of the frame structure 240 may extend from the sidewall 241 within the space.

According to an embodiment, the frame structure 240 may support or accommodate other components included in the electronic device 101. For example, the display 201 may be disposed on one surface of the frame structure 240 facing one direction (e.g., the +z direction), and the display 201 may be supported by the support portion 243 of the frame structure 240. For another example, a first printed circuit board 250, a second printed circuit board 252, a battery 270, and a rear camera 212 may be disposed on the other surface facing a direction opposite to the one direction (e.g., the −z direction) of the frame structure 240. The first printed circuit board 250, the second printed circuit board 252, the battery 270, and the rear camera 212 may be mounted on a recess defined by the sidewall 241 and/or the support portion 243 of the frame structure 240.

According to an embodiment, the first printed circuit board 250, the second printed circuit board 252, and the battery 270 may be coupled to the frame structure 240, respectively. For example, the first printed circuit board 250 and the second printed circuit board 252 may be fixedly disposed in the frame structure 240 through a coupling member such as a screw. For example, the battery 270 may be fixedly disposed on the frame structure 240 through an adhesive member (e.g., a double-sided tape). However, embodiments of the disclosure are not limited to the above-described example.

According to an embodiment, a cover plate 260 may be disposed between the first printed circuit board 250 and the rear plate 211. According to an embodiment, the cover plate 260 may be disposed on the first printed circuit board 250. For example, the cover plate 260 may be disposed on a surface facing the −z direction of the first printed circuit board 250.

According to an embodiment, the cover plate 260 may at least partially overlap the first printed circuit board 250 with respect to the z-axis. According to an embodiment, the cover plate 260 may cover at least a partial area of the first printed circuit board 250. Through this, the cover plate 260 may protect the first printed circuit board 250 from physical impact or prevent the connector coupled to the first printed circuit board 250 from being separated.

According to an embodiment, the cover plate 260 may be fixedly disposed on the first printed circuit board 250 through a coupling member (e.g., a screw), or may be coupled to the frame structure 240 together with the first printed circuit board 250 through the coupling member.

According to an embodiment, the display 201 may be disposed between the frame structure 240 and the front plate 202. For example, a front plate 202 may be disposed on one side (e.g., a +z direction) of the display 201 and a frame structure 240 may be disposed on the other side (e.g., a −z direction).

According to an embodiment, the front plate 202 may be coupled to the display 201. For example, the front plate 202 and the display 201 may adhere to each other through an optical adhesive member (e.g., optically clear adhesive (OCA) or optically clear resin (OCR)) interposed therebetween.

According to an embodiment, the front plate 202 may be coupled to the frame structure 240. For example, the front plate 202 may include an outside portion extending outside the display 201 when viewed in the z-axis direction, and may adhere to the frame structure 240 through an adhesive member (e.g., a double-sided tape) disposed between the outside portion of the front plate 202 and the frame structure 240 (e.g., the sidewall 241). However, embodiments of the disclosure are not limited by the above-described example.

According to an embodiment, the first printed circuit board 250 and/or the second printed circuit board 252 may be equipped with a processor (e.g., a processor 120 of FIG. 1), a memory (e.g., a memory 130 of FIG. 1), and/or an interface (e.g., an interface 177 of FIG. 1). The processor may include, for example, one or more of a central processing unit, an application processor, a graphic processing unit, an image signal processor, a sensor hub processor, or a communication processor. The memory may include, for example, a volatile memory or a nonvolatile memory. The interface may include, for example, a high definition multimedia interface (HDMI), a universal serial bus (USB) interface, an SD card interface, and/or an audio interface. The interface may electrically or physically connect the electronic device 101 to an external electronic device, and may include a USB connector, an SD card/MMC connector, or an audio connector. According to an embodiment, the first printed circuit board 250 and the second printed circuit board 252 may be operatively or electrically connected to each other through a connection member (e.g., a flexible printed circuit board).

According to an embodiment, the battery 270 may supply power to at least one component of the electronic device 101. For example, the battery 270 may include a rechargeable secondary cell or a fuel cell. At least a portion of the battery 270 may be disposed on substantially the same plane as the first printed circuit board 250 and/or the second printed circuit board 252.

The electronic device 101 according to an embodiment may include an antenna module (e.g., an antenna module 197 of FIG. 1). According to an embodiment, the antenna module may be disposed between the rear plate 211 and the battery 270. The antenna module may include, for example, a near field communication (NFC) antenna, a wireless charging antenna, and/or a magnetic secure transmission (MST) antenna. The antenna module, for example, may perform short-range communication with an external device, or wirelessly transmit and receive power to and from the external device.

According to an embodiment, the front camera 205 may be disposed in at least a portion (e.g., a support portion 243) of the frame structure 240 so that the lens may receive external light through a partial area (e.g., a camera area 237) of the front plate 202.

According to an embodiment, the rear camera 212 may be disposed between the frame structure 240 and the rear plate 211. According to an embodiment, the rear camera 212 may be electrically connected to the first printed circuit board 250 through a connection member (e.g., a connector). According to an embodiment, the rear camera 212 may be disposed such that the lens may receive external light through a camera area 284 of the rear plate 211 of the electronic device 101.

According to an embodiment, the camera area 284 may be formed on the surface (e.g., a rear surface 200B of FIG. 2) of the rear plate 211. According to an embodiment, the camera area 284 may be formed to be at least partially transparent so that external light may be incident to the lens of the rear camera 212. According to an embodiment, at least a portion of the camera area 284 may protrude from the surface of the rear plate 211 to a predetermined height. However, embodiments of the disclosure are not limited to thereto, and in another embodiment, the camera area 284 may form a plane substantially the same as the surface of the rear plate 211.

According to an embodiment, the housing (e.g., a housing 210 of FIG. 2) of the electronic device 101 may mean a configuration or structure forming at least a portion of the exterior of the electronic device 101. In this regard, at least a portion of the front plate 202, the frame structure 240, and/or the rear plate 211 forming the exterior of the electronic device 101 may be referred to as the housing 210 of the electronic device 101.

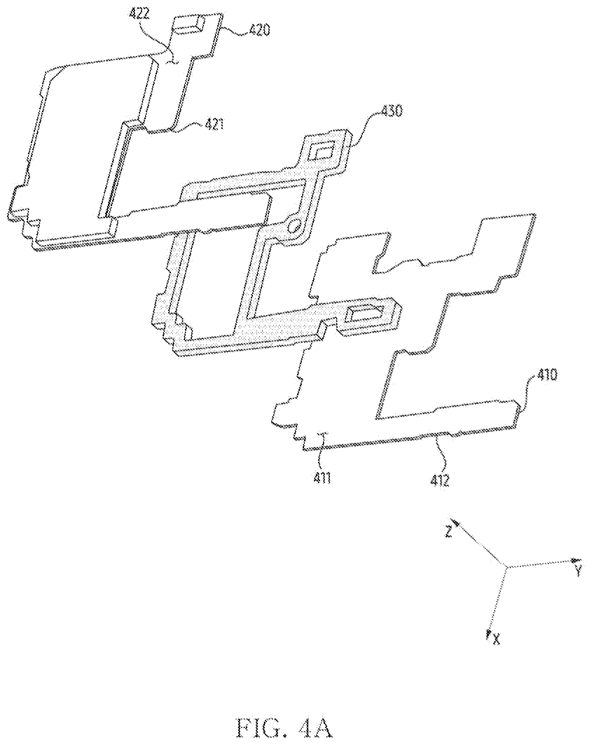

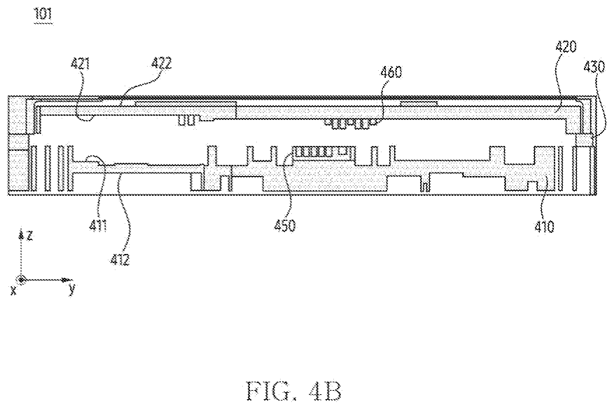

FIG. 4A is a partially exploded perspective view of an exemplary electronic device. FIG. 4B is a partial cross-sectional view of the exemplary electronic device.

Referring to FIGS. 4A and 4B, an electronic device 101 may include a first printed circuit board 410 (e.g., the first printed circuit board 250 of FIG. 3) and a second printed circuit board 420 (e.g., the second printed circuit board 252 of FIG. 3).

According to an embodiment, the second printed circuit board 420 may face the first printed circuit board 410. The second printed circuit board 420 may be disposed on the first printed circuit board 410. In the disclosure, it should be understood that when an element is referred to as being “on” another element, it may be directly on the other element or there may be intervening elements therebetween. For example, in the disclosure, “B disposed on A” may refer to “B disposed over A.” For example, in the disclosure, “B disposed on A” may refer to “B disposed under A.” For example, in the disclosure, “B disposed on A” may refer to “B faced away from A.” For example, “a second printed circuit board 420 disposed on the first printed circuit board 410” may refer to “a second printed circuit board 420 in contact with the first printed circuit board 410.” For example, “a second printed circuit board 420 disposed on the first printed circuit board 410” may refer to “a second printed circuit board 420 faced away from the first printed circuit board 410.” A structure in which the second printed circuit board 420 is disposed on the first printed circuit board 410 may be referred to as a PCB stack-up, but examples of the structure are not limited to the above example.

For example, the second printed circuit board 420 may be spaced apart from the first printed circuit board 410. At least some of the second printed circuit board 420 may face the first printed circuit board 410. For example, at least some of the second printed circuit board 420 may overlap the first printed circuit board 410 when viewing the first printed circuit board 410 from above. For example, a plurality of electronic components may be mounted on each of the first printed circuit board 410 and the second printed circuit board 420. At least some (i.e., one or more) of the electronic components mounted on the first printed circuit board 410 may face at least some of the electronic components mounted on the second printed circuit board 420. Since at least some of the first printed circuit board 410 is spaced apart from the second printed circuit board 420, the electronic components disposed on the first printed circuit board 410 may be spaced apart from the electronic components disposed on the second printed circuit board 420.

According to an embodiment, the first printed circuit board 410 may include a first surface 411 facing the second printed circuit board 420 and a third surface 412 opposite to the first surface 411. The second printed circuit board 420 may include a second surface 421 facing the first printed circuit board 410 and a fourth surface 422 opposite to the second surface 421. For example, the first surface 411 and the second surface 421 may face each other. For example, the first surface 411 may be faced away from the second surface 421. For example, the first surface 411 may be a surface closest to the second printed circuit board 420 among all the surfaces of the first printed circuit board 410. For example, the second surface 421 may be a surface closest to the first printed circuit board 410 among all the surfaces of the second printed circuit board 420. For example, the third surface 412 may be a surface furthest from the second printed circuit board 420 among all the surfaces of the first printed circuit board 410. For example, the fourth surface 422 may be a surface furthest from the first printed circuit board 410 among all the surfaces of the second printed circuit board 420.

According to an embodiment, the electronic device 101 may further include a first set of electronic components 450 disposed on the first surface 411 of the first printed circuit board 410 and a second set of electronic components 460 disposed on the second surface 421 of the second printed circuit board 420. For example, at least some of the first set of electronic components 450 may be supplied power from a power management module (e.g., the power management module 188 and/or the battery 189 of FIG. 1) of the electronic device 101 through the first printed circuit board 410. For example, at least some of the second set of electronic components 460 may be supplied power from the power management module 188 and/or the battery 189 through the second printed circuit board 420. For example, since the first surface 411 faces the second surface 421, at least some of the first set of electronic components 450 mounted on the first surface 411 may face at least some of the second set of electronic components 460 mounted on the second surface 421. For example, since the first surface 411 is spaced apart from the second surface 421, each of the first set of electronic components 450 mounted on the first surface 411 may be spaced apart from the second set of electronic components 460 mounted on the second surface 421.

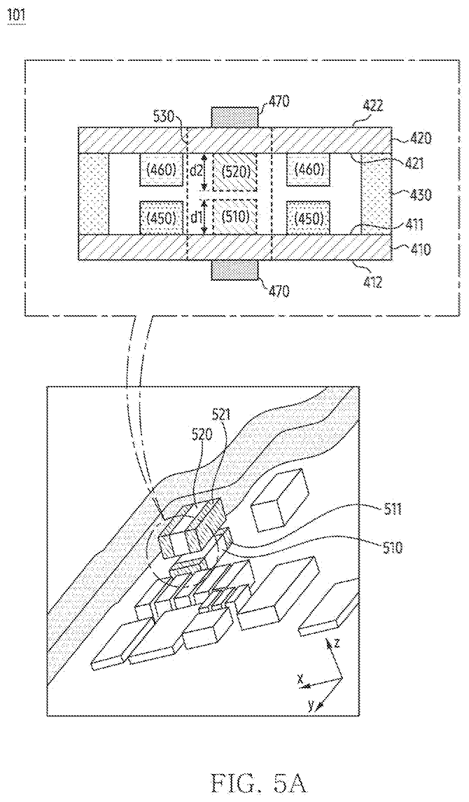

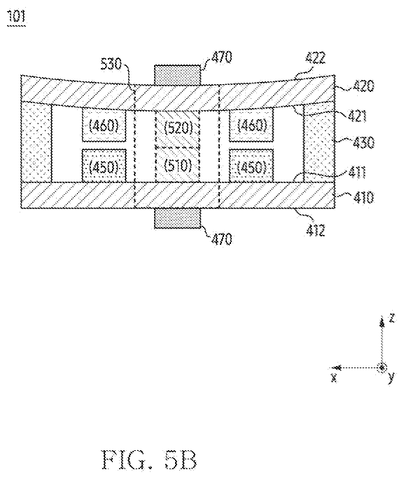

In some embodiments, the electronic device 101 may include the first set of electronic components 450 and the second set of electronic components 460, but embodiments of the disclosure are not limited thereto. The electronic device 101 may further include a third set of electronic components (e.g., a third set of electronic components 470 of FIG. 5A) positioned on the third surface 412 of the first printed circuit board 410 and/or the fourth surface 422 of the second printed circuit board 420. The third set of electronic components 470 may be spaced apart from the first set of electronic components 450 and the second set of electronic components 460. In addition, terms such as “first set” and “second set” may be used simply to distinguish the corresponding components from other components, and therefore do not limit the corresponding components on another side (e.g., the number of corresponding components). For example, the first set of electronic components 450 may include one or more electronic components disposed on the first surface 411. For example, the second set of electronic components 460 may include one or more electronic components disposed on the second surface 421.

According to an embodiment, the electronic device 101 may further include the third set of electronic components 470 disposed on at least some of the third surface 412 opposite to the first surface 411 of the first printed circuit board 410 and the fourth surface 422 opposite to the second surface 421 of the second printed circuit board 420. The first support member 510 and the second support member 520 may be disposed at positions corresponding to at least some of the third set of electronic components 470.

For example, at least some of the third set of electronic components 470 may at least partially overlap the first support member 510 when viewing the first printed circuit board 410 from above (e.g., when viewing in a −z direction). For example, at least some of the third set of electronic components 470 may be disposed on substantially the same axis as the first support member 510 based on x-axis and y-axis. For example, at least some of the third set of electronic components 470 may at least partially overlap the second support member 520 when viewing the second printed circuit board 420 from above (e.g., when viewing in a +z direction). For example, at least some of the third set of electronic components 470 may be disposed on substantially the same axis as the second support member 520 based on the x-axis and y-axis. For example, the electronic device 101 may include a supporting region 530 that is relatively vulnerable to external impact. At least some of the third set of electronic components 470 may be disposed on the supporting region 530. The first support member 510 and the second support member 520 may be disposed at positions corresponding to the at least some of the third set of electronic components 470 disposed on the supporting region 530 in the supporting region 530. The at least some of the third set of electronic components 470 disposed on the supporting region 530 may have the greatest height based on z-axis among electronic components disposed outside a space surrounded by the first printed circuit board 410, the second printed circuit board 420, and an interposer 430. The at least some of the third set of electronic components 470 may be electronic components that are relatively vulnerable to the external impact as an external structure (e.g., the rear plate 211 of FIG. 2) of the electronic device 101 is deformed by the external impact. The first support member 510 and the second support member 520 may reduce malfunction of electronic components around the first support member 510 and the second support member 520 due to the external impact by being disposed in a position corresponding to the relatively vulnerable electronic component.

According to an embodiment, the electronic device 101 may further include the interposer 430 between the first printed circuit board 410 and the second printed circuit board 420 surrounding a space between the first surface 411 of the first printed circuit board 410 and the second surface 421 of the second printed circuit board 420. For example, the interposer 430 may separate the first printed circuit board 410 from the second printed circuit board 420. For example, the interposer 430 may be in contact with the first surface 411 and the second surface 421. For example, the interposer 430 may surround the first set of electronic components 450 disposed on the first surface 411 and the second set of electronic components 460 disposed on the second surface 421. The electronic device 101 may provide a space for the first set of electronic components 450 and the second set of electronic components 460 and reduce contact of the first set of electronic components 450 with the second set of electronic components 460 by including the interposer 430.

According to an embodiment, a structure in which electronic components (e.g., the first set of electronic components 450, the second set of electronic components 460, and the third set of electronic components 470) are disposed on the first surface 411, the second surface 421, the third surface 412, and the fourth surface 422, respectively, may be referred to as a 4-surface mounting structure of a printed circuit board. In the 4-surface mounting structure, since the first surface 411 and the second surface 421 face each other, at least some of the first set of electronic components 450 and at least some of the second set of electronic components 460 may be in contact by the external impact. The electronic device 101 may include a structure for reducing the malfunction of the at least some of the first set of electronic components 450 and/or the at least some of the second set of electronic components 460 by contacting the at least some of the first set of electronic components 450 and the at least some of the second set of electronic components 460 with each other. The structure for reducing the malfunction will be described later in FIG. 5A and below.

In FIGS. 2 and 3, the electronic device 101 may correspond to a device having a bar shape in FIGS. 2 and 3, but shapes of the electronic device 101 are not limited to the device having the bar shape.

For example, the electronic device 101 may include a first housing and a second housing movable with respect to the first housing. The electronic device 101 may include a flexible display (e.g., the display 201 of FIG. 2) including a deformable region along the second housing that moves with respect to the first housing. The flexible display may provide a user with various user experiences by including the region in which at least some is rolled into the first housing along the second housing that moves with respect to the first housing or exposed outside the first housing. The electronic device 101 including the flexible display including a deformable region along the second housing that moves with respect to the first housing may include the structure for reducing the malfunction of the at least some of the first set of electronic components 450 and/or the at least some of the second set of electronic components 460 by contacting the at least some of the first set of electronic components 450 and the at least some of the second set of electronic components 460 with each other.

For example, the electronic device 101 may include the first housing, the second housing, and a hinge structure rotatably connecting the first housing and the second housing. The electronic device may include a flexible display including a deformable region disposed on the hinge structure and extends from the first housing, across over the hinge structure, to the second housing. The electronic device 101 may provide the user with various user experiences by including the hinge structure rotatably connecting the first housing and the second housing. The electronic device 101 including the flexible display including the deformable region disposed on the hinge structure may include a structure for reducing the malfunction of the at least some of the first set of electronic components 450 and/or the at least some of the second set of electronic components 460 by contacting the at least some of the first set of electronic components 450 and the at least some of the second set of electronic components 460 with each other.

The electronic device 101 according to the above-described embodiment may increase space for electronic components mounted on the first printed circuit board 410 and/or the second printed circuit board 420 in the electronic device 101 by including the first printed circuit board 410 and the second printed circuit board 420 disposed on the first printed circuit board 410.

FIG. 5A illustrates a portion of an exemplary electronic device in a first state. FIG. 5B illustrates a portion of an exemplary electronic device in a second state.

Referring to FIGS. 5A and 5B, an electronic device 101 may include a first printed circuit board 410, and a second printed circuit board 420 facing the first printed circuit board 410 and spaced apart from the first printed circuit board 410. The electronic device 101 may further include an interposer 430 between the first printed circuit board 410 and the second printed circuit board 420 surrounding a space between a first surface 411 of the first printed circuit board 410 facing the second printed circuit board 420 and a second surface 421 of the second printed circuit board 420 facing the first printed circuit board 410. The electronic device 101 may further include a first set of electronic components 450 disposed on the first surface 411 and a second set of electronic components 460 disposed on the second surface 421.

Hereinafter, an overlapping description of the configuration described in FIGS. 4A and 4B will be omitted.

Referring to FIGS. 5A and 5B, the electronic device 101 may include a first support member 510 disposed on the first surface 411 of the first printed circuit board 410 facing the second printed circuit board 420. The electronic device 101 may include a second support member 520 disposed on the second printed circuit board 420 and facing the first support member 510. The second support member 520 may be configured to come into contact with the first support member 510, for example, by an external force.

For example, the first support member 510 and the second support member 520 may be disposed in a space surrounded by the first surface 411, the second surface 421, and the interposer 430. The first support member 510 may be disposed on the second support member 520 in the space. For example, the first support member 510 may be faced away from the second support member 520. For example, the first support member 510 may be attached on the first surface 411 to face the second support member 520. The second support member 520 may be attached on the second surface 421 to face the first support member 510.

A first state of the electronic device 101 may be a state in which the first support member 510 and the second support member 520 are spaced apart. For example, the first state may be a state in which the first support member 510 and the second support member 520 are faced away. For example, the first state may be a state in which the electronic device 101 includes a gap between the first support member 510 and the second support member 520.

For example, the electronic device 101 may include a supporting region 530 in which the first support member 510 and the second support member 520 are disposed. The supporting region 530 may include a portion of the first printed circuit board 410 connected with the first support member 510 and a portion of the second printed circuit board 420 connected with the second support member 520. The first state may be a state in which the supporting region 530 is not damaged. The first state may be a state in which a portion of the first printed circuit board 410 and/or a portion of the second printed circuit board 420 included in the supporting region 530 are not deformed. The first state may be a state in which a portion of the first printed circuit board 410 included in the supporting region 530 is not bent toward the second printed circuit board 420. The first state may be a state in which a portion of the second printed circuit board 420 included in the supporting region 530 is not bent toward the first printed circuit board 410. However, embodiments of the disclosure are not limited thereto, and the first state may include a plurality of states in which the first support member 510 and the second support member 520 are not in contact.

A second state of the electronic device 101 may be a state in which the first support member 510 and the second support member 520 are in contact. For example, the second state may be a state in which the first support member 510 and the second support member 520 are connected. For example, the second state may be a state in which the electronic device 101 does not include a gap between the first support member 510 and the second support member 520.

For example, the second state may be a state in which at least some of the supporting region 530 in which the first support member 510 and the second support member 520 are disposed is damaged. For example, the second state may be a state in which the first support member 510 and the second support member 520 are in contact by deforming a portion of the first printed circuit board 410 and/or a portion of the second printed circuit board 420 included in the supporting region 530. For example, the second state may be a state in which at least some of the first printed circuit board 410 included in the supporting region 530 is bent toward the second printed circuit board 420. For example, the second state may be a state in which at least some of the second printed circuit board 420 included in the supporting region 530 is bent toward the first printed circuit board 410. However, embodiments of the disclosure are not limited thereto. For example, the second state may include a plurality of states in which the first support member 510 and the second support member 520 are in contact by deforming at least some of the supporting region 530.

For example, the first support member 510 and the second support member 520 may face each other. While the electronic device 101 changes from the first state to the second state, at least some of the supporting region 530 may be deformed by an external impact. For example, a portion of the first printed circuit board 410 included in the supporting region 530 may be bent toward the second printed circuit board 420. By bending the portion of the first printed circuit board 410, the first support member 510 may be moved toward the second support member 520. For example, a portion of the second printed circuit board 420 included in the supporting region 530 may be bent toward the first printed circuit board 410. By bending the portion of the second printed circuit board 420, the second support member 520 may be moved toward the first support member 510. Since the first support member 510 and the second support member 520 are disposed to face each other, in case that at least some of the supporting region 530 is deformed, the second support member 520 may be configured to come into contact with the first support member 510. For example, in the second state, the first support member 510 may support the second support member 520. The first support member 510 may reduce damage to the second printed circuit board 420 due to the external impact by supporting the second support member 520. For example, in the second state, the second support member 520 may support the first support member 510. The second support member 520 may reduce damage to the first printed circuit board 410 due to the external impact by supporting the first support member 510.

According to an embodiment, the first support member 510 may overlap the second support member 520, when viewing the first surface 411 of the first printed circuit board 410 from above. For example, the first support member 510 may be disposed at a position corresponding to the second support member 520 in a space surrounded by the first printed circuit board 410, the second printed circuit board 420, and the interposer 430. For example, a surface of the first support member 510 facing the second printed circuit board 420 may face a surface of the second support member 520 facing the first printed circuit board 410. The surface of the first support member 510 facing the second printed circuit board 420 may overlap the surface of the second support member 520 facing the first printed circuit board 410 in the second state of the electronic device 101 in which the first support member 510 and the second support member 520 are in contact. The first support member 510 may reduce damage to the first printed circuit board 410 and/or the second printed circuit board 420 in the second state, by overlapping the second support member 520 when viewing the first surface 411 of the first printed circuit board 410 from above.

According to an embodiment, a length d1 of the first support member 510 extending from the first surface 411 toward the second surface 421 may be greater than a length of each of a first set of electronic components 450 extending from the first surface 411 toward the second surface 421. A length d2 of the second support member 520 extending from the second surface 421 toward the first surface 411 may be greater than a length of each of a second set of electronic components 460 extending from the second surface 421 toward the first surface 411.

For example, the length d1 of the first support member 510 extending from the first surface 411 toward the second surface 421 may be greater than a maximum length of the first set of electronic components 450 extending from the first surface 411 toward the second surface 421. The length d2 of the second support member 520 extending from the second surface 421 toward the first surface 411 may be greater than a maximum length of the second set of electronic components 460 extending from the second surface 421 toward the first surface 411. For example, the gap between the first support member 510 and the second support member 520 may be smaller than a gap between the first set of electronic components 450 and the second set of electronic components 460. Since the length d1 of the first support member 510 is greater than the length of each of the first set of electronic components 450 and the length d2 of the second support member 520 is greater than the length of each of the second set of electronic components 460, the electronic device 101 may reduce the malfunction of the first set of electronic components 450 and/or the second set of electronic components 460 generated by contacting the first set of electronic components 450 and the second set of electronic components 460.

According to an embodiment, the first set of electronic components 450 may be spaced apart from the second set of electronic components 460 while changing from the first state of the electronic device 101 in which the first support member 510 and the second support member 520 are spaced apart to the second state of the electronic device 101 in which the first support member 510 and the second support member 520 are in contact. For example, since the length d1 of the first support member 510 is greater than the maximum length of the first set of electronic components 450 and the length d2 of the second support member 520 is greater than the maximum length of the second set of electronic components 460, the first set of electronic components 450 may be spaced apart from the second set of electronic components 460 in the second state. For example, since the first support member 510 supports the second surface 421 through the second support member 520 and the second support member 520 supports the first surface 411 through the first support member 510 in the second state, the first set of electronic components 450 may be spaced apart from the second set of electronic components 460. The electronic device 101 may include the first support member 510 and the second support member 520, which avoid a contact between the first set of electronic components 450 and the second set of electronic components 460. Thus, the electronic device 101 may reduce the malfunction of the first set of electronic components 450 and/or the second set of electronic components 460, which is caused by the contact between the first set of electronic components 450 and the second set of electronic components 460.

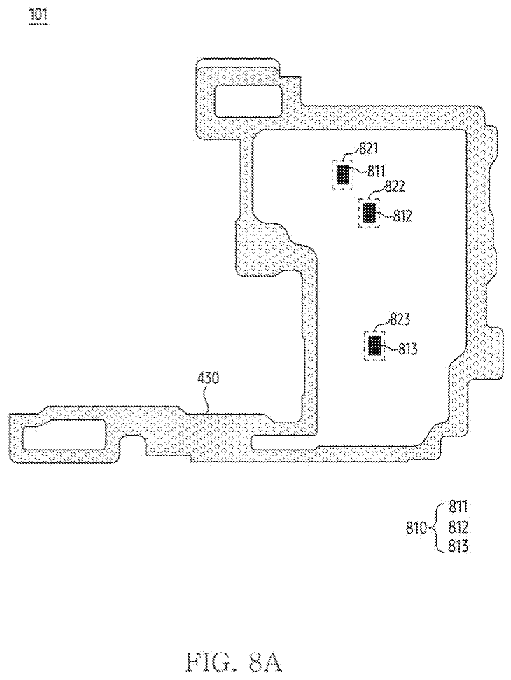

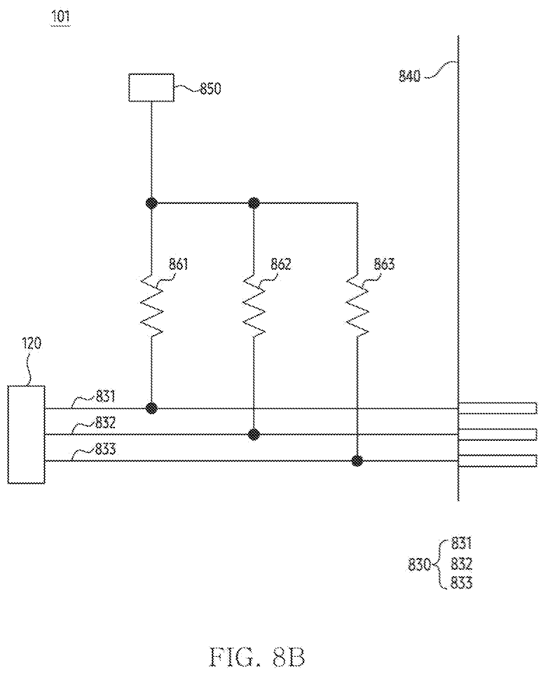

In some embodiments, the electronic device 101 may include the first support member 510 and the second support member 520, but embodiments of the display are not limited thereto. The electronic device 101 may include a plurality of supporting regions (e.g., the supporting regions 530) that are relatively susceptible to deformation due to external impact. The electronic device 101 may include sets of support members (e.g., sets of support members 810 of FIG. 8A) disposed on each of the plurality of supporting regions and paired with each other. A disposition of a plurality of support members in each of the plurality of supporting regions will be described later in FIG. 8A and below.

According to an embodiment, the first support member 510 may include a first electrode 511. The second support member 520 may include a second electrode 521 configured to come into contact with the first electrode 511. For example, the first electrode 511 may form at least some of the first support member 510. The first electrode 511 may be exposed to the outside of the first support member 510. The second electrode 521 may form at least some of the second support member 520. The second electrode 521 may be exposed to the outside of the second support member 520, thus the second electrode 521 may be configured to come into contact with the first electrode 511 of the first support member 510. For example, at least a portion of the second electrode 521 may face at least a portion of the first electrode 511, thus the portion of the second electrode 521 may be configured to come into contact with the first electrode 511. For example, the second electrode 521 may be spaced apart from the first electrode 511 in the first state of the electronic device 101 in which the first support member 510 and the second support member 520 are spaced apart. The second electrode 521 may be in contact at least some of the first electrode 511 in the second state of the electronic device 101 in which the first support member 510 and the second support member 520 are in contact.

For example, the first electrode 511 may be electrically connected to the first printed circuit board 410. The second electrode 521 may be electrically connected to the second printed circuit board 420. The first electrode 511 may provide a conductive path for current from the first printed circuit board 410 to the second printed circuit board 420 by being in contact with the second electrode 521. The electronic device 101 may be configured to identify the second state of the electronic device 101 in which the first support member 510 and the second support member 520 are in contact through the current. Identifying contact between the first support member 510 and the second support member 520 will be described later in FIG. 8A and below.

According to an embodiment, the first support member 510 including the first electrode 511 and/or the second support member 520 including the second electrode 521 may be referred to as an electronic element including at least one of a dummy cap and a capacitor. By including at least one of the dummy cap or the capacitor, the first support member 510 and the second support member 520 may simplify a process in which the first support member 510 and the second support member 520 are disposed on the first printed circuit board 410 and the second printed circuit board 420, respectively, and reduce the malfunction of electronic components around the first support member 510 and the second support member 520.

According to an embodiment, the first electrode 511 may extend in a first direction in the first support member 510. The second electrode 521 may extend in a second direction different from the first direction in the second support member 520. According to an embodiment, the first direction in which the first electrode 511 extends may be perpendicular to the second direction in which the second electrode 521 extends. For example, the first electrode 511 may extend in a direction parallel to +x direction or −x direction in the first support member 510. The second electrode 521 may extend in a direction parallel to +y direction or −y direction in the second support member 520. However, embodiments of the disclosure are not limited thereto. Since the direction in which the first electrode 511 extends is different from the direction in which the second electrode 521 extends, the electronic device 101 may reduce a contact area between the first electrode 511 and the second electrode 521. The electronic device 101 may reduce damage to the first electrode 511 and the second electrode 521 by reducing the contact area between the first electrode 511 and the second electrode 521. According to an embodiment, the first electrode 511 may be disposed on both ends of the first support member 510. The second electrode 521 may be disposed on both ends of the second support member 520 so as to extend in a direction perpendicular to the direction in which the first electrode 511 extends. For example, the first electrode 511 may extend in a direction parallel to a major axis of the first support member 510. The second electrode 521 may extend in a direction parallel to a minor axis of the second support member 520 overlapping the first support member 510. However, embodiments of the disclosure are not limited thereto.

According to an embodiment, each of the first support member 510 and the second support member 520 may be deformable. For example, by deforming the first printed circuit board 410 and/or the second printed circuit board 420 in the supporting region 530, the first support member 510 may be in contact with the second support member 520. The first support member 510 may be deformed by the second support member 520. The second support member 520 may be deformed by the first support member 510. For example, the first support member 510 and the second support member 520 may include rubber, but are not limited thereto. Since the first support member 510 and the second support member 520 are deformable, the electronic device 101 may reduce damage to the first printed circuit board 410 and/or the second printed circuit board 420 due to the contact between the first support member 510 and the second support member 520. For example, the contract between the first support member 510 and the second support member 520 may be caused by an external force or an external impact.

The electronic device 101 according to the above-described embodiment may reduce damage to the first printed circuit board 410 and the second printed circuit board 420 by including the first support member 510 and the second support member 520 facing the first support member 510 and configured to come into contact with the first support member 510. The first support member 510 and the second support member 520 may reduce contact between the first set of electronic components 450 on the first surface 411 and the second set of electronic components 460 on the second surface 421 by being configured to come into contact with each other. The first support member 510 and the second support member 520 may provide the user of the electronic device 101 with various user experiences by including the first electrode 511 and the second electrode 521, respectively.

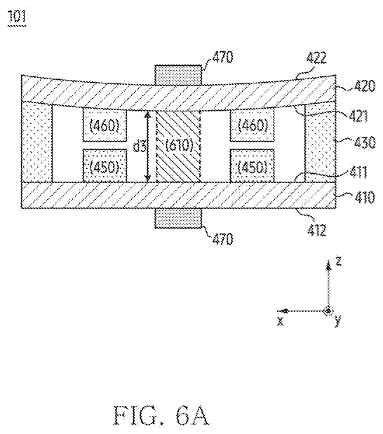

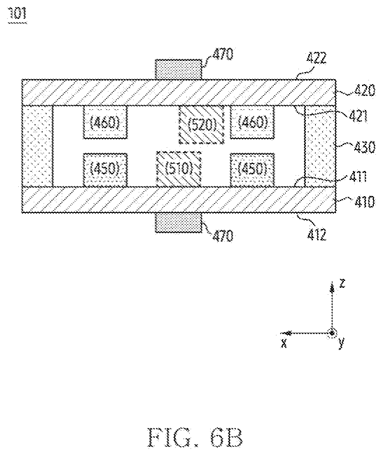

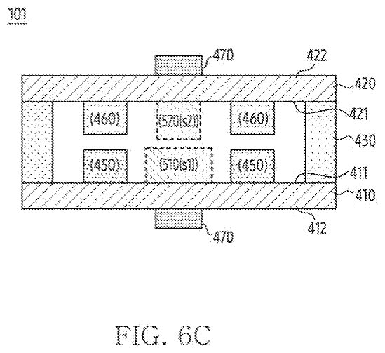

FIGS. 6A, 6B, and 6C are partial cross-sectional views of an exemplary electronic device.

Referring to FIGS. 6A, 6B, and 6C, an electronic device 101 may include a first printed circuit board 410, and a second printed circuit board 420 facing the first printed circuit board 410 and spaced apart from the first printed circuit board 410. The electronic device 101 may further include an interposer 430 between the first printed circuit board 410 and the second printed circuit board 420 surrounding a space between a first surface 411 of the first printed circuit board 410 facing the second printed circuit board 420 and a second surface 421 of the second printed circuit board 420 facing the first printed circuit board 410. The electronic device 101 may further include a first set of electronic components 450 disposed on the first surface 411 and a second set of electronic components 460 disposed on the second surface 421.

Referring to FIG. 6A, the electronic device 101 may include a support member 610 between the first printed circuit board 410 and the second printed circuit board 420. For example, in contrast to FIGS. 5A and 5B, either a first support member (e.g., the first support member 510 of FIG. 5A) and a second support member (e.g., the second support member 520 of FIG. 5A) may be omitted. For example, a length d3 of the support member 610 extending from the first surface 411 to the second surface 421 may be greater than a sum of a maximum length of the electronic component included in the first set of electronic components 450 and a maximum length of the electronic component included in the second set of electronic components 460. For example, the support member 610 may be in contact with the first printed circuit board 410 and the second printed circuit board 420 as the first printed circuit board 410 and/or the second printed circuit board 420 are deformed by an external impact. The support member 610 may reduce contact of the first set of electronic components 450 with the second set of electronic components 460 by being configured to support the first printed circuit board 410 and the second printed circuit board 420.

Referring to FIGS. 6B and 6C, the electronic device 101 may include a first support member 510 disposed on the first surface 411 of the first printed circuit board 410 facing the second printed circuit board 420, and a second support member 520 disposed on the second surface 421 of the second printed circuit board 420 facing the first printed circuit board 410.

Referring to FIG. 6B, a portion of the first support member 510 may face a portion of the second support member 520. A remaining portion of the first support member 510 may face the second surface 421 of the second printed circuit board 420. A remaining portion of the second support member 520 may face the first surface 411 of the first printed circuit board 410. Since the portion of the first support member 510 faces the portion of the second support member 520, it may be in contact with the portion of the second support member 520 in case that the first printed circuit board 410 and/or the second printed circuit board 420 are deformed. According to an embodiment, the first support member 510 may include a first electrode (e.g., the first electrode 511 of FIG. 5A) on a portion facing the second support member 520. The second support member 520 may include a second electrode (e.g., the second electrode 521 of FIG. 5A) configured to come into contact with the first electrode 511 on a portion facing the first support member 510. However, embodiments of the disclosure are not limited thereto, the electronic device 101 may include the first support member 510 and the second support member 520 configured to partially contact with each other and paired.

Referring to FIG. 6C, a size s1 of the first support member 510 may be different from a size s2 of the second support member 520. For example, a region where the first support member 510 is disposed may include a region where the second support member 520 is disposed when viewing the first surface 411 from above. For example, when viewing the first surface 411 from above, a portion of the first support member 510 may overlap the second support member 520. For example, a portion of the first support member 510 may face the second support member 520. According to an embodiment, the first support member 510 may include the first electrode 511 on a portion facing the second support member 520. The second support member 520 may include a second electrode 521 configured to be in contact with the first electrode 511. However, without being limited thereto, in some embodiments, the electronic device 101 may include the first support member 510 and the second support member 520 that are different in size and pair with each other. The first support member 510 and the second support member 520 may be configured to come into contact with each other.

According to the above-described embodiment, the electronic device 101 may reduce contact between the first set of electronic components 450 on the first surface 411 and the second set of electronic components 460 on the second surface 421 by including at least one support member (e.g., the support member 610 of FIG. 6A, the first support member 510 and the second support member 520 of FIGS. 6B and 6C) that spaces the first set of electronic components 450 and the second set of electronic components 460 apart from each other.

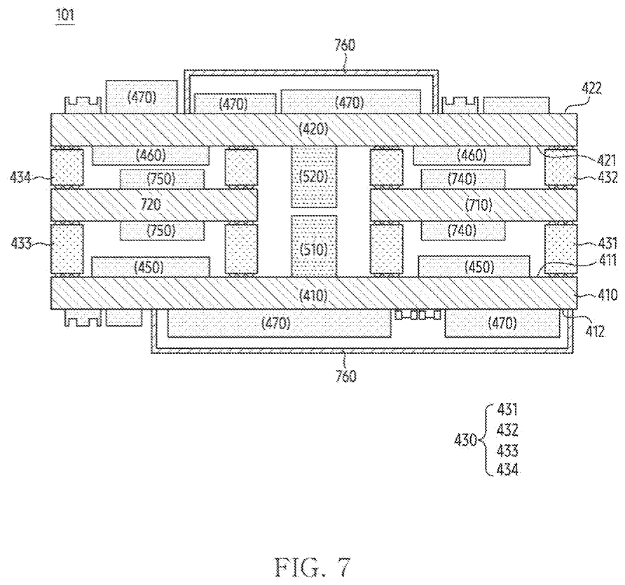

FIG. 7 is a partial cross-sectional view of an exemplary electronic device.

Referring to FIG. 7, an electronic device 101 may include a first printed circuit board 410, and a second printed circuit board 420 facing the first printed circuit board 410 and spaced apart from the first printed circuit board 410. The electronic device 101 may further include an interposer 430 between a first surface 411 of the first printed circuit board 410 facing the second printed circuit board 420 and a second surface 421 of the second printed circuit board 420 facing the first printed circuit board 410. The electronic device 101 may further include a first set of electronic components 450 disposed on the first surface 411 and a second set of electronic components 460 disposed on the second surface 421.

According to an embodiment, the electronic device 101 may further include a third printed circuit board 710 disposed between the first printed circuit board 410 and the second printed circuit board 420 and spaced apart from a first support member 510 and a second support member 520. The electronic device 101 may further include a fourth set of electronic components 740 mounted on the third printed circuit board 710. For example, a portion of the fourth set of electronic components 740 may face the first surface 411 of the first printed circuit board 410. A remaining portion of the fourth set of electronic components 740 may face the second surface 421 of the second printed circuit board 420. The first support member 510 and the second support member 520 may be configured to come into contact with each other (e.g., when an external force is applied). Accordingly, the first support member 510 and the second support member 520 may keep the fourth set of electronic components 740 apart from the first set of electronic components 450 on the first surface 411 and/or the second set of electronic components 460 on the second surface 421.

In an embodiment, the electronic device 101 may include the third printed circuit board 710 between the first printed circuit board 410 and the second printed circuit board 420, but embodiments of the disclosure are not limited thereto. For example, the electronic device 101 may further include a fourth printed circuit board 720 disposed between the first printed circuit board 410 and the second printed circuit board 420 and spaced apart from the third printed circuit board 710. The electronic device 101 may further include a fifth set of electronic components 750 mounted on the fourth printed circuit board 720. The electronic device 101 may include interposers 431, 432, 433, and 434 for electronic components (e.g., the first set of electronic components 450, the second set of electronic components 460, the fourth set of electronic components 740, and the fifth set of electronic components 750) between the first printed circuit board 410 and the second printed circuit board 420. The first support member 510 and the second support member 520 may be configured to come into contact with each other (e.g., when an external force is applied). Accordingly, the first support member 510 and the second support member 520 may space the fifth set of electronic components 750 apart from the first set of electronic components 450 on the first surface 411 and/or the second set of electronic components 460 on the second surface 421 by being configured to contact each other. However, without being limited thereto, the electronic device 101 may include the first support member 510 and the second support member 520 configured to keep apart (or away from each other) a plurality of electronic components disposed on each of the plurality of printed circuit boards between the first printed circuit board 410 and the second printed circuit board 420.

According to an embodiment, the electronic device 101 may include the first support member 510 disposed on the first surface 411 of the first printed circuit board 410 and the second support member 520 facing the first support member 510 and disposed on the second surface 421 of the second printed circuit board 420 facing the first surface 411, but embodiments of the disclosure are not limited thereto. The electronic device 101 may include the plurality of printed circuit boards on which electronic components are disposed to face each other as illustrated in FIG. 7. The electronic device 101 may include a plurality of support members including the first support member 510 and the second support member 520 to reduce malfunction of the electronic components due to a contact of the electronic components facing each other according to external impact. For example, the electronic device 101 may include support members disposed between the first printed circuit board 410 and the third printed circuit board 710 and facing at least some of each other to reduce contact between the first set of electronic components 450 and the fourth set of electronic components 740. For example, the electronic device 101 may include support members disposed between the first printed circuit board 410 and the fourth printed circuit board 720 and facing at least some of each other to reduce contact between the first set of electronic components 450 and the fifth set of electronic components 750. For example, the electronic device 101 may include support members disposed between the second printed circuit board 420 and the third printed circuit board 710 and facing at least some of each other to reduce contact between the second set of electronic components 460 and the fourth set of electronic components 740. For example, the electronic device 101 may include support members disposed between the second printed circuit board 420 and the fourth printed circuit board 720 and facing at least some of each other to reduce contact between the second set of electronic components 460 and the fifth set of electronic components 750. However, it is not limited thereto. It should be noted that the electronic device 101 may include support members for spacing electronic components facing each other apart and does not limit the number and disposition relationship of support members.

According to an embodiment, the electronic device 101 may further include a third set of electronic components 470 disposed on a third surface 412 of the first printed circuit board 410 and/or a fourth surface 422 of the second printed circuit board 420. The third set of electronic components 470 may be disposed outside a space surrounded by the first printed circuit board 410, the second printed circuit board 420, and the interposer 430 by being disposed on the third surface 412 and/or the fourth surface 422. In order to protect the third set of electronic components 470 disposed outside the space from external impact, the electronic device 101 may further include at least one shield can 760 that covers at least some of the third set of electronic components 470. The electronic device 101 may reduce damage to electronic components around the first printed circuit board 410 and the second printed circuit board 420 from external impact by including the first support member 510 and the second support member 520 in the space and the at least one shield can 760 outside the space.

According to the above-described embodiment, the electronic device 101 may reduce the malfunction of electronic components in the electronic device 101 by including electronic components (e.g., the fourth set of electronic components 740 and the fifth set of electronic components 750) mounted on at least one printed circuit board (e.g., the third printed circuit board 710 and the fourth printed circuit board 720) between the first printed circuit board 410 and the second printed circuit board 420 and support members (e.g., the first support member 510 and the second support member 520) configured to keep apart each of electronic components (e.g., the first set of electronic components 450 and the second set of electronic components 460) mounted on the first surface 411 and the second surface 421.

FIG. 8A illustrates a portion of an exemplary electronic device in which a plurality of support members is disposed. FIG. 8B is a circuit diagram for detecting an abnormal state of an electronic device.

Referring to FIGS. 8A and 8B, an electronic device 101 may include a first printed circuit board (e.g., the first printed circuit board 410 of FIG. 4A), and a second printed circuit board (e.g., the second printed circuit board 420 of FIG. 4A) facing the first printed circuit board 410 and spaced apart from the first printed circuit board 410. The electronic device 101 may further include an interposer 430 between the first printed circuit board 410 and the second printed circuit board 420 surrounding a space between a first surface (e.g., the first surface 411 of FIG. 4A) of the first printed circuit board 410 facing the second printed circuit board 420 and a second surface (e.g., the second surface 421 of FIG. 4A) of the second printed circuit board 420 facing the first printed circuit board 410. The electronic device 101 may further include a first set of electronic components (e.g., the first set of electronic components 450 of FIG. 4B) disposed on the first surface 411 and a second set of electronic components (e.g., the second set of electronic components 460 of FIG. 4B) disposed on the second surface 421.

Referring to FIG. 8A, the electronic device 101 may include sets of support members 810. For example, the sets of support members 810 may include a first set of support members 811, a second set of support members 812, and a third set of support members 813. For example, each of the first set of support members 811, the second set of support members 812, and the third set of support members 813 may include two support members paired with each other (e.g., the first support member 510 and the second support member 520 of FIG. 5A). For example, the electronic device 101 may include a first supporting region 821 in which the first set of support members 811 is disposed, a second supporting region 822 in which the second set of support members 812 is disposed, and a third supporting region 823 in which the third set of support members 813 is disposed. Each of the supporting regions 821, 822, and 823 may include a portion of the first printed circuit board 410 and a portion of the second printed circuit board 420.

For example, in a case that a portion of the first printed circuit board 410 and/or a portion of the second printed circuit board 420 included in at least some of the supporting regions 821, 822, and 823 are damaged, two support members included in the at least some of the supporting regions 821, 822, and 823 and paired with each other may be in contact with each other. The two support members paired with each other may include an electrode (e.g., the first electrode 511 of FIG. 5A and the second electrode 521 of FIG. 5B), respectively. The electronic device 101 may be configured to identify a degree of damage to the at least some among the supporting regions 821, 822, and 823 in which the two support members paired with each other are disposed through contact of electrodes disposed on each of the two support members paired with each other.

Referring to FIG. 8B, the electronic device 101 may include a processor 120, at least one damage detection circuit 830, an analog to digital converting (ADC) port 840, and a VDD 850.

The at least one damage detection circuit 830 may be included in the first printed circuit board 410. The at least one damage detection circuit 830 may be connected to electrodes disposed on the first printed circuit board 410 in the supporting regions 821, 822, and 823, respectively. Electrodes disposed on the second printed circuit board 420 in the supporting regions 821, 822, and 823 may be connected to a ground of the electronic device 101, respectively. For example, the at least one damage detection circuit 830 may include a first damage detection circuit 831, a second damage detection circuit 832, and a third damage detection circuit 833. The first damage detection circuit 831 may be connected to an electrode disposed on the first printed circuit board 410 in the first supporting region 821. The second damage detection circuit 832 may be connected to an electrode disposed on the first printed circuit board 410 in the second supporting region 822. The third damage detection circuit 833 may be connected to an electrode disposed on the first printed circuit board 410 in the third supporting region 823.

The ADC port 840 may be connected to the at least one damage detection circuit 830. The ADC port 840 may be configured to detect a change in voltage of at least some of the at least one damage detection circuit 830. For example, voltage of the first damage detection circuit 831 connected to at least some of the electrodes may be changed as the electrodes paired with each other in the first supporting region 821 are contacted. For example, referring to FIG. 5A, current flowing through a first electrode 511 may vary as the first electrode 511 is in contact with a second electrode 521. Since the current flowing through the first electrode 511 varies, a voltage of the at least one damage detection circuit 830 connected to the first electrode 511 may be changed. The ADC port 840 may be configured to measure whether and/or a degree of damage of the supporting regions 821, 822, and 823 where the sets of support members 810 are disposed, respectively, by being configured to detect a change in the voltage of the at least one damage detection circuit 830 connected with the ADC port 840.

The VDD 850 may be connected to the at least one damage detection circuit 830. The VDD 850 may be configured to provide a driving voltage to the at least one damage detection circuit 830. For example, the VDD 850 may provide the driving voltage to the at least one damage detection circuit 830 through a potential difference caused by each of resistors 861, 862, and 863.

The processor 120 may be configured to identify the degree of damage to the first printed circuit board 410 and/or the second printed circuit board 420 included in the supporting regions 821, 822, and 823 through the at least one damage detection circuit 830 and the ADC port 840.

In an embodiment, the electronic device 101 may include the first supporting region 821, the second supporting region 822, and the third supporting region 823, but embodiments of the disclosure are not limited thereto. The electronic device 101 may include a plurality of supporting regions in which the first printed circuit board 410 and/or the second printed circuit board 420 are relatively vulnerable to damage. The electronic device 101 may reduce damage to the electronic device 101 by being configured to identify at least some of the plurality of supporting regions that are damaged through the at least one damage detection circuit 830 and the ADC port 840.

According to the above-described embodiment, the electronic device 101 may reduce damage to the first printed circuit board 410 and the second printed circuit board 420 as the first printed circuit board 410 and/or the second printed circuit board 420 includes sets of support members 810 paired with relatively vulnerable supporting regions 821, 822, and 823, respectively.

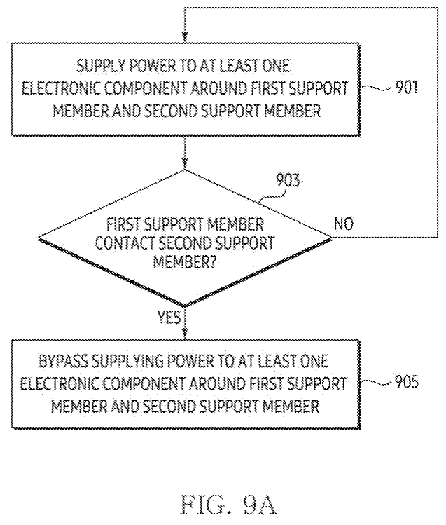

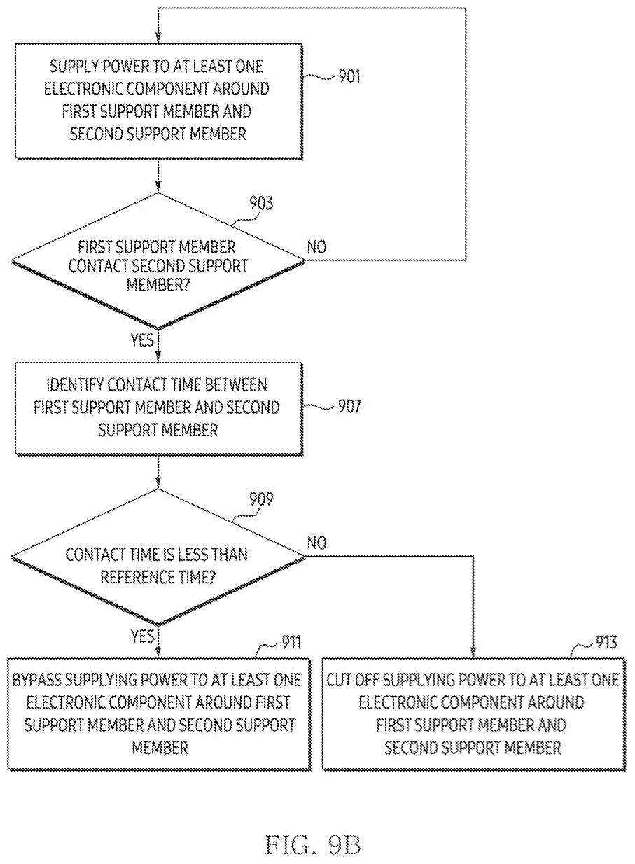

FIGS. 9A and 9B are flow charts illustrating an operation of a processor of an exemplary electronic device.

Operations of FIGS. 9A and 9B may be performed by an electronic device 101 of FIGS. 5A and 5B. The electronic device 101 may further include a processor (e.g., the processor 120 of FIG. 1).

According to an example, the processor 120 may be configured to identify contact between a first support member (e.g., the first support member 510 of FIG. 5A) and a second support member (e.g., the second support member 520 of FIG. 5A) through a first electrode (e.g., the first electrode 511 of FIG. 5A) and the second electrode (e.g., the second electrode 521 of FIG. 5A). For example, when the first support member 510 is in contact with the second support member 520, the first electrode 511 may be in contact with the second electrode 521. The processor 120 may be configured to identify the contact between the first support member 510 and the second support member 520 by detecting a change in voltage generated by contact between the first electrode 511 and the second electrode 521 through an ADC port (e.g., the ADC port 840 of FIG. 8B).

In operation 901, the processor 120 may be configured to supply power to at least one electronic component around the first support member 510 and the second support member 520. For example, the processor 120 may be configured to supply power to at least some around the first support member 510 among a first set of electronic components (e.g., the first set of electronic components 450 of FIG. 5A). For example, the processor 120 may be configured to supply power to at least some around the second support member 520 among a second set of electronic components (e.g., the second set of electronic components 460 of FIG. 5A).

In operation 903, the processor 120 may be configured to identify whether the first support member 510 and the second support member 520 are in contact through the first electrode 511 and the second electrode 521. For example, the processor 120 may detect a change in voltage generated by contact between the first electrode 511 and the second electrode 521 through at least one damage detection circuit (e.g., the at least one damage detection circuit 830 of FIG. 8B) and the ADC port 840. The processor 120 may be configured to identify whether the first support member 510 and the second support member 520 are in contact through the change in the voltage.

Referring to FIG. 9A, in operation 905, the processor 120 may bypass supplying power to at least one electronic component around the first support member 510 and the second support member 520 in response to the contact between the first support member 510 and the second support member 520 identified through the contact between the first electrode 511 and the second electrode 521. For example, the first support member 510 may contact the second support member 520 due to an external impact. The processor 120 may reduce malfunction of the at least one electronic component by bypassing supplying power to the at least one electronic component around the first support member 510 and the second support member 520 based on identifying the contact between the first support member 510 and the second support member 520.

Referring to FIG. 9B, in operation 907, the processor 120 may be configured to identify a contact time (e.g., “t”) between the first support member 510 and the second support member 520. For example, the processor 120 may identify the time at which the voltage changed through the ADC port 840 while the first electrode 511 and the second electrode 521 are in contact.

In operation 909, the processor 120 may be configured to identify whether the contact time (e.g., “t”) between the first support member 510 and the second support member 520 is less than a reference time t1. For example, the processor 120 may identify whether the time at which the voltage changed through the ADC port 840 is less than the reference time t1, while the first electrode 511 and the second electrode 521 are in contact.

In operation 911, the processor 120 may be configured to bypass supplying power to at least one electronic component around the first support member 510 and the second support member 520 in response to identifying the contact time (e.g., “t”) between the first support member 510 and the second support member 520 less than the reference time t1. For example, due to an external impact, the first support member 510 and the second support member 520 may be temporarily in contact. While the first support member 510 and the second support member 520 are in contact for the contact time (e.g., “t”) less than the reference time t1, the processor 120 may bypass supplying power to at least one electronic component around the first support member 510 and the second support member 520. The processor 120 may be configured to supply power to the at least one electronic component while the first support member 510 and the second support member 520 are spaced apart.

In operation 913, the processor 120 may be configured to cut off supplying power to at least one electronic component around the first support member 510 and the second support member 520 in response to identifying a contact time (e.g., “t”) greater than or equal to the reference time t1. For example, at least some of a first printed circuit board 410 and/or a second printed circuit board 420 may be plastic deformed due to an external impact. The first support member 510 and the second support member 520 may be in contact for the contact time t1 greater than or equal to the reference time t1 due to plastic deformation of the first printed circuit board 410 and/or the second printed circuit board 420. The processor 120 may reduce damage to the electronic device 101 caused by the at least one electronic component by being configured to cut off supplying power to the at least one electronic component around the first support member 510 and the second support member 520 in case that the first support member 510 and the second support member 520 have the contact time t1 greater than or equal to the reference time t1.

The processor 120 of the electronic device 101 according to the above-described embodiment may reduce malfunction of the at least one electronic component around the first support member 510 and the second support member 520 by being configured to identify the contact between the first support member 510 and the second support member 520. The processor 120 may reduce damage to the electronic device 101 caused by the at least one electronic component and/or the at least one electronic component by being configured to identify the contact time between the first support member 510 and the second support member 520.

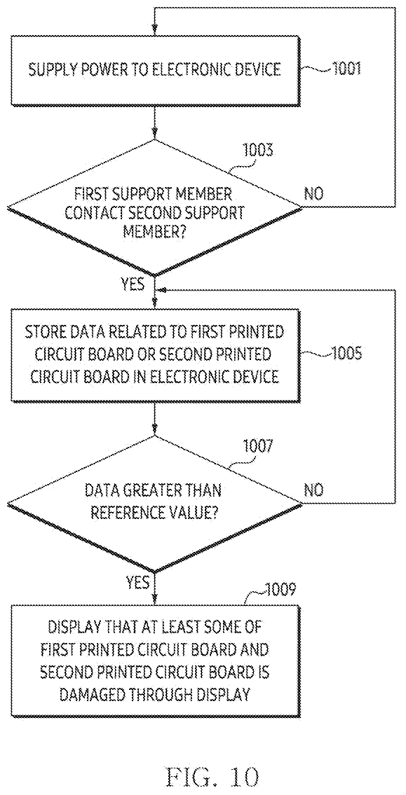

FIG. 10 is a flow chart illustrating an operation of a processor of an exemplary electronic device.

Operations of FIG. 10 may be performed by an electronic device 101 of FIGS. 5A and 5B. The electronic device 101 may further include a processor (e.g., the processor 120 of FIG. 1). Operation 1003 of FIG. 10 may be an operation corresponding to operation 903 of FIGS. 9A and 9B, respectively. According to an embodiment, the electronic device 101 may further include a display (e.g., the display 201 of FIG. 2). The display 201 may be configured to provide visual information to a user.

In operation 1001, the processor 120 may be configured to supply power to the electronic device 101. For example, the processor 120 may supply power to the electronic device 101 through a power management module (e.g., the power management module 188 of FIG. 1) and/or through a battery (e.g., the battery 189 of FIG. 1) of the electronic device 101.

In operation 1005, the processor 120 may be configured to store data related to a first printed circuit board (e.g., the first printed circuit board 410 of FIG. 4A) or a second printed circuit board (e.g., the second printed circuit board 420 of FIG. 4A) in the electronic device 101, in response to identifying contact between a first support member (e.g., the first support member 510 of FIG. 5A) and a second support member (e.g., the second support member 520 of FIG. 5A). For example, the processor 120 may store information related to damage to the first printed circuit board 410 and/or the second printed circuit board 420 in the electronic device 101 through a contact time (e.g., “t”) between the first support member 510 and the second support member 520. For example, the processor 120 may store the information related to the damage to the first printed circuit board 410 and/or the second printed circuit board 420 in the electronic device 101 through an amount of change in voltage identified through contact between a first electrode (e.g., the first electrode 511 of FIG. 5A) and a second electrode (e.g., the second electrode 521 of FIG. 5A). For example, the processor 120 may store data related to the first printed circuit board 410 or the second printed circuit board 420 in a memory (e.g., the memory 130 of FIG. 1) of the electronic device 101 in response to identifying the contact between the first support member 510 and the second support member 520, but embodiments of the disclosure are not limited thereto. For example, the processor 120 may be configured to store the information in a server (e.g., the server 108 of FIG. 1) and/or another electronic device (e.g., the electronic device 102 and the electronic device 104 of FIG. 1). For example, the electronic device 101 may provide a breakage history of the electronic device 101 based on stored data related to the first printed circuit board 410 or the second printed circuit board 420.

In operation 1007, the processor 120 may be configured to identify whether the data related to the first printed circuit board 410 or the second printed circuit board 420 is greater than a reference value (e.g., “a”). For example, the processor 120 may identify whether data related to damage to the first printed circuit board 410 and/or the second printed circuit board 420 is greater than the reference value (e.g., “a”) through the amount of change in voltage identified through the contact between the first electrode 511 and the second electrode 521. The processor 120 may be configured to store the data in the electronic device 101 based on the data less than or equal to the reference value (e.g., “a”).

In operation 1009, the processor 120 may be configured to display through the display 201 that at least some of the first printed circuit board 410 and the second printed circuit board 420 are damaged, based on data related to the first printed circuit board 410 or the second printed circuit board 420 greater than the reference value (e.g., “a”). For example, at least some of data related to damage to the first printed circuit board 410 or the second printed circuit board 420 may be greater than the reference value (e.g., “a”). The processor 120 may notify the user through the display 201 that at least some of the first printed circuit board 410 and the second printed circuit board 420 is damaged, based on the at least some of the data being greater than the reference value (e.g., “a”). However, without being limited thereto, the processor 120 may notify the user through a sound output module (e.g., the sound output module 155 of FIG. 1) and/or a speaker module that at least some of the first printed circuit board 410 or the second printed circuit board 420 is damaged, based on at least some of the data greater than the reference value (e.g., “a”).

The electronic device 101 according to the above-described embodiment may provide the user of the electronic device 101 with various user experiences by being configured to store data related to the first printed circuit board 410 and the second printed circuit board 420. The processor 120 of the electronic device 101 may reduce damage to the electronic device 101 by being configured to display through the display 201 that at least some of the first printed circuit board 410 and the second printed circuit board 420 is damaged.

An electronic device (e.g., the electronic device 101 of FIG. 1) according to the above-described embodiment may comprise a first printed circuit board (e.g., the first printed circuit board 410 of FIG. 4A). The electronic device may comprise a second printed circuit board (e.g., the second printed circuit board 420 of FIG. 4A) facing the first printed circuit board and disposed on the first printed circuit board. The electronic device may comprise a first support member (e.g., the first support member 510 of FIG. 5A) disposed on a first surface (e.g., the first surface 411 of FIG. 4A) of the first printed circuit board facing the second printed circuit board. The electronic device may comprise a second support member (e.g., the second support member 520 of FIG. 5A) disposed on a second surface (e.g., the second surface 421 of FIG. 4A) of the second printed circuit board facing the first printed circuit board, and facing the first support member and spaced apart from the first support member so as to be contactable with the first support member. The electronic device may comprise an interposer (e.g., the interposer 430 of FIG. 4A) between the first printed circuit board and the second printed circuit board surrounding a space between the first surface and the second surface. According to the above-mentioned embodiment, the electronic device may reduce damage to the first printed circuit board and the second printed circuit board by including the first support member and the second support member. The above-mentioned embodiment may have various effects including the above-mentioned effect.

According to an embodiment, the first support member may at least partially overlap the second support member when viewing the first surface from above. According to the above-mentioned embodiment the first support member may reduce damage to the first printed circuit board and the second printed circuit board by overlapping the second support member. The above-mentioned embodiment may have various effects including the above-mentioned effect.

The electronic device according to an embodiment may further comprise a first set of electronic components (e.g., the first set of electronic components 450 of FIG. 4B) disposed on the first surface and a second set of electronic components (e.g., the second set of electronic components 460 of FIG. 4B) disposed on the second surface. A length (e.g., a length d1 of FIG. 5A) of the first support member extending from the first surface toward the second surface may be greater than a length of each of the first set of electronic components extending from the first surface toward the second surface. A length (e.g., a length d2 of FIG. 5A) of the second support member extending from the second surface toward the first surface may be greater than a length of each of the second set of electronic components extending from the second surface toward the first surface. According to the above-mentioned embodiment, the electronic device may reduce contact between the first set of electronic components and the second set of electronic components as the length of the first support member is greater than the length of each of the first set of electronic components and the length of the second support member is greater than the length of the second set of electronic components.

According to an embodiment, the first set of electronic components may be spaced apart from the second set of electronic components while changing from a first state of the electronic device in which the first support member and the second support member are spaced apart to a second state of the electronic device in which the first support member and the second support member contact each other. According to the above-mentioned embodiment, the electronic device may separate the first set of electronic components and the second set of electronic components by including the first support member and the second support member.

The electronic device according to an embodiment may further comprise a third set of electronic components (e.g., the third set of electronic components 470 of FIG. 4A) disposed on at least some of a second surface (e.g., the second surface 421 of FIG. 4A) opposite to the first surface of the first printed circuit board and a fourth surface (e.g., the fourth surface 422 of FIG. 4A) opposite to the second surface of the second printed circuit board. The first support member and the second support member may be disposed at positions corresponding to at least some of electronic components among the third set of electronic components. According to the above-mentioned embodiment, the electronic device may reduce malfunction of electronic components around the first support member and the second support member by including the first support member and the second support member disposed at positions corresponding to at least some of electronic components among the third set of electronic components.

According to an embodiment, the first support member may include a first electrode (e.g., the first electrode 511 of FIG. 5A). The second support member may include a second electrode (e.g., the second electrode 521 of FIG. 5A) configured to come into contact with the first electrode. According to the above-mentioned embodiment, the electronic device may be configured to identify contact between the first support member and the second support member by including the first electrode and the second electrode.

According to an embodiment, the first electrode may extend in a first direction in the first support member. The second electrode may extend in a second direction different from the first direction in the second support member. According to the above-mentioned embodiment, the first electrode may reduce damage to the first electrode and the second electrode due to contact with the second electrode by extending in a direction different from the direction in which the second electrode extends.

According to an embodiment, each of the first support member and the second support member may deformable. According to the above-mentioned embodiment, each of the first support member and the second support member may reduce damage to the first printed circuit board and the second printed circuit board by being deformable.

According to an embodiment, a size of the first support member (e.g., the size s1 of FIG. 6C) may be different from a size of the second support member (e.g., the size s2 of FIG. 6C). According to the above-mentioned embodiment, the electronic device may reduce damage to the first printed circuit board and the second printed circuit board as the size of the first support member is different from the size of the second support member.

The electronic device according to an embodiment may further comprise a third printed circuit board (e.g., the third printed circuit board 710 of FIG. 7) disposed between the first printed circuit board and the second printed circuit board and spaced apart from the first support member and the second support member. According to the above-mentioned embodiment, the electronic device may provide an additional space for electronic components in the electronic device by further comprising the third printed circuit board.

The electronic device according to an embodiment may further comprise a processor (e.g., the processor 120 of FIG. 1). The first support member may include a first electrode. The second support member may include a second electrode configured to come into contact with the first electrode. The processor may be configured to identify contact between the first support member and the second support member through contact between the first electrode and the second electrode. According to the above-mentioned embodiment, the processor may provide a user of the electronic device with various user experiences by being configured to identify contact between the first support member and the second support member.

According to an embodiment, the processor may be configured to supply power to at least one electronic component around the first support member and the second support member while the first support member is spaced apart from the second support member. The processor may be configured to bypass or cut off supplying power to the at least one electronic component in response to contact between the first support member and the second support member identified through contact between the first electrode and the second electrode. According to the above-mentioned embodiment, the processor may provide a user of the electronic device various user experiences by being configured to identify the contact between the first support member and the second support member.

According to an embodiment, the processor may be configured to identify a contact time between the first support member and the second support member through contact between the first electrode and the second electrode. The processor may be configured to bypass supplying power to the at least one electronic component around the first support member and the second support member in response to identifying the contact time less than a reference time. The processor may be configured to cut off supplying power to the at least one electronic component in response to identifying the contact time greater than or equal to the reference time. According to the above-mentioned embodiment, the processor may provide a user of the electronic device with various user experiences by being configured to identify contact between the first support member and the second support member.

The electronic device according to an embodiment may further comprise a processor. The processor may be configured to identify contact between the first support member and the second support member. The processor may be configured to store data related to the first printed circuit board or the second printed circuit board in the electronic device in response to identifying contact between the first support member and the second support member. According to the above-mentioned embodiment, the processor may provide a user of the electronic device with various user experiences by being configured to identify contact between the first support member and the second support member.

According to an embodiment, the processor may be configured to provide information indicating at least some of the first printed circuit board and the second printed circuit board are damaged based on at least some of the data to a user. According to the above-mentioned embodiment, the processor may provide a user of the electronic device with various user experiences by being configured to identify contact between the first support member and the second support member.

An electronic device according to an embodiment may comprise a first printed circuit board. The electronic device may comprise a second printed circuit board facing the first printed circuit board and disposed on the first printed circuit board. The electronic device may comprise a first support member disposed on a first surface of the first printed circuit board facing the second printed circuit board. The electronic device may comprise a second support member disposed on a second surface of the second printed circuit board facing the first printed circuit board, and facing the first support member and spaced apart from the first support member so as to be contactable with the first support member. The electronic device may comprise a first set of electronic components disposed on the first surface and a second set of electronic components disposed on the second surface. The electronic device may comprise an interposer between the first printed circuit board and the second printed circuit board surrounding a space between the first surface and the second surface. A sum of a length of the first support member extending from the first surface toward the second surface and a length of the second support member extending from the second surface toward the first surface may be greater than a sum of a length of one electronic component among the first set of electronic components extending from the first surface toward the second surface and a length of another electronic component among the second set of electronic components facing at least some of the one electronic component extending from the second surface toward the first surface. According to the above-mentioned embodiment, the electronic device may reduce damage to the first printed circuit board and the second printed circuit board by including the first support member and the second support member.

According to an embodiment, a length of the first support member extending from the first surface toward the second surface may be greater than a length of each of the first set of electronic components extending from the first surface toward the second surface. A length of the second support member extending from the second surface toward the first surface may be greater than a length of each of the second set of electronic components extending from the second surface toward the first surface. According to the above-mentioned embodiment, the electronic device may reduce contact between the first set of electronic components and the second set of electronic components as the length of the first support member is greater than the length of each of the first set of electronic components and the length of the second support member is greater than the length of each of the second set of electronic components.

The electronic device according to an embodiment may further comprise a processor. The first support member may include a first electrode. The second support member may include a second electrode configured to come into contact with the first electrode. The processor may be configured to identify contact between the first support member and the second support member through contact between the first electrode and the second electrode. According to the above-mentioned embodiment, the processor may provide a user of the electronic device with various user experiences by being configured to identify contact between the first support member and the second support member.

According to an embodiment, the processor may be configured to supply power to at least one electronic component around the first support member and the second support member while the first support member is spaced apart from the second support member. The processor may be configured to bypass or cut off supplying power to the at least one electronic component in response to the contact between the first support member and the second support member identified through contact between the first electrode and the second electrode. According to the above-mentioned embodiment, the processor may provide a user of the electronic device with various user experiences by being configured to identify contact between the first support member and the second support member.

According to an embodiment, the processor may be configured to identify a contact time between the first support member and the second support member through contact between the first electrode and the second electrode. The processor may be configured to bypass supplying power to the at least one electronic component around the first support member and the second support member in response to identifying the contact time less than a reference time. The processor may be configured to cut off supplying power to the at least one electronic component in response to identifying the contact time greater than or equal to the reference time. According to the above-mentioned embodiment, the processor may provide a user of the electronic device with various user experiences by being configured to identify contact between the first support member and the second support member.

The electronic device according to various embodiments may be one of various types of electronic devices. The electronic devices may include, for example, a portable communication device (e.g., a smartphone), a computer device, a portable multimedia device, a portable medical device, a camera, a wearable device, or a home appliance. According to an embodiment of the disclosure, the electronic devices are not limited to those described above.

It should be appreciated that various embodiments of the present disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. It is to be understood that a singular form of a noun corresponding to an item may include one or more of the things unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” or “connected with” another element (e.g., a second element), it means that the element may be coupled with the other element directly (e.g., wiredly), wirelessly, or via a third element.

As used in connection with various embodiments of the disclosure, the term “module” may include a unit implemented in hardware, software, or firmware, and may interchangeably be used with other terms, for example, “logic,” “logic block,” “part,” or “circuitry”. A module may be a single integral component, or a minimum unit or part thereof, adapted to perform one or more functions. For example, according to an embodiment, the module may be implemented in a form of an application-specific integrated circuit (ASIC).

Various embodiments as set forth herein may be implemented as software (e.g., the program 140) including one or more instructions that are stored in a storage medium (e.g., internal memory 136 or external memory 138) that is readable by a machine (e.g., the electronic device 101). For example, a processor (e.g., the processor 120) of the machine (e.g., the electronic device 101) may invoke at least one of the one or more instructions stored in the storage medium, and execute it, with or without using one or more other components under the control of the processor. This allows the machine to be operated to perform at least one function according to the at least one instruction invoked. The one or more instructions may include a code generated by a complier or a code executable by an interpreter. The machine-readable storage medium may be provided in the form of a non-transitory storage medium. Wherein, the term “non-transitory” simply means that the storage medium is a tangible device, and does not include a signal (e.g., an electromagnetic wave), but this term does not differentiate between a case in which data is semi-permanently stored in the storage medium and a case in which the data is temporarily stored in the storage medium.

According to an embodiment, a method according to various embodiments of the disclosure may be included and provided in a computer program product. The computer program product may be traded as a product between a seller and a buyer. The computer program product may be distributed in the form of a machine-readable storage medium (e.g., compact disc read only memory (CD-ROM)), or be distributed (e.g., downloaded or uploaded) online via an application store (e.g., PlayStore™), or between two user devices (e.g., smart phones) directly. If distributed online, at least part of the computer program product may be temporarily generated or at least temporarily stored in the machine-readable storage medium, such as memory of the manufacturer's server, a server of the application store, or a relay server.

According to various embodiments, each component (e.g., a module or a program) of the above-described components may include a single entity or multiple entities, and some of the multiple entities may be separately disposed in different components. According to various embodiments, one or more of the above-described components may be omitted, or one or more other components may be added. Alternatively or additionally, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

What is claimed is:

1. An electronic device comprising:
a first printed circuit board;
a second printed circuit board, facing the first printed circuit board, disposed over the first printed circuit board;
a first support member disposed on a first surface of the first printed circuit board;
a second support member, disposed on a second surface of the second printed circuit board, wherein the support member faces the first printed circuit board, is spaced apart from the first support member, and is configured to come into contact with the first support member by an external force applied to the electronic device; and
an interposer between the first printed circuit board and the second printed circuit board, surrounding an area between the first surface and the second surface.

2. The electronic device of claim 1, wherein the first support member partially overlaps the second support member when viewing the first surface from above.

3. The electronic device of claim 1, further comprising:
a first set of electronic components disposed on the first surface; and
a second set of electronic components disposed on the second surface,
wherein the first support member and the first set of electronic components extend from the first surface toward the second surface,
wherein the second support member and the second set of electronic components extend from the second surface toward the first surface,
wherein a length of the first support member is greater than a length of each of the first set of electronic components, and
wherein a length of the second support member is greater than a length of each of the second set of electronic components.

4. The electronic device of claim 3, wherein the first set of electronic components space apart from the second set of electronic components while changing from a first state of the electronic device in which the first support member and the second support member are spaced apart to a second state of the electronic device in which the first support member and the second support member are contacted with each other.

5. The electronic device of claim 3, further comprising a third set of electronic components disposed on at least some of a third surface opposite to the first surface of the first printed circuit board and a fourth surface opposite to the second surface of the second printed circuit board, and
wherein, the first support member and the second support member are disposed at positions corresponding to at least some of electronic components among the third set of electronic components.

6. The electronic device of claim 1, wherein the first support member includes a first electrode, and
wherein the second support member includes a second electrode configured to come into contact with the first electrode.

7. The electronic device of claim 6, wherein the first electrode extends in a first direction in the first support member,
wherein the second electrode extends in a second direction different from the first direction in the second support member.

8. The electronic device of claim 1, wherein each of the first support member and the second support member is deformable.

9. The electronic device of claim 1, wherein a size of the first support member is different from a size of the second support member.

10. The electronic device of claim 1, further comprising a third printed circuit board, disposed between the first printed circuit board and the second printed circuit board, spaced apart from the first support member and the second support member.

11. The electronic device of claim 1, further comprising:
at least one processor; and
memory, comprising one or more storage mediums, storing instructions,
wherein the first support member comprises a first electrode,
wherein the second support member comprises a second electrode configured to come into contact with the first electrode,
wherein the instructions, when being executed by the at least one processor individually or collectively, cause the electronic device to, based on the contact between the first electrode and the second electrode, identify that the first support member and the second support member are contacted with each other.

12. The electronic device of claim 11, wherein the instructions, when being executed by the at least one processor individually or collectively, further cause the electronic device to:
supply power to at least one electronic component around the first support member and the second support member while the first support member is spaced apart from the second support member; and
bypass or cut off supplying power to the at least one electronic component in response to the contact between the first support member and the second support member identified through contact between the first electrode and the second electrode.

13. The electronic device of claim 12, wherein the instructions, when being executed by the at least one processor individually or collectively, further cause the electronic device to:
identify a contact time between the first support member and the second support member through contact between the first electrode and the second electrode, and
bypass the supplying power to the at least one electronic component around the first support member and the second support member in response to identifying the contact time less than a reference time, and
cut off the supplying power to the at least one electronic component in response to identifying the contact time equal to or greater than the reference time.

14. The electronic device of claim 1, further comprising:
at least one processor; and
memory, comprising one or more storage mediums, storing instructions that, when executed by the at least one processor individually or collectively, cause the electronic device to:
wherein the instructions, when being executed by the at least one processor, cause the electronic device to:
identify contact between the first support member and the second support member, and
store data related to the first printed circuit board or the second printed circuit board in the electronic device in response to identifying contact between the first support member and the second support member.

15. The electronic device of claim 14, wherein the instructions, when being executed by the at least one processor individually or collectively, further cause the electronic device to provide information indicating at least some of the first printed circuit board and the second printed circuit board are damaged based on at least some of the data to a user.

16. An electronic device comprising:
a first printed circuit board;
a second printed circuit board, facing the first printed circuit board, disposed on the first printed circuit board;
a first support member disposed on a first surface of the first printed circuit board facing the second printed circuit board;
a second support member disposed on a second surface of the second printed circuit board facing the first printed circuit board, and facing the first support member and spaced apart from the first support member so as to be contactable with the first support member;
a first set of electronic components disposed on the first surface;
a second set of electronic components disposed on the second surface; and
an interposer between the first printed circuit board and the second printed circuit board surrounding a space between the first surface and the second surface;
wherein, a sum of a length of the first support member extending from the first surface toward the second surface and a length of the second support member extending from the second surface toward the first surface is greater than a sum of a length of one electronic component among the first set of electronic components extending from the first surface toward the second surface and a length of another electronic component among the second set of electronic components facing at least portion of the one electronic component extending from the second surface toward the first surface.

17. The electronic device of claim 16, wherein, a length of the first support member extending from the first surface toward the second surface is greater than a length of each of the first set of electronic components extending from the first surface toward the second surface, and
wherein, a length of the second support member extending from the second surface toward the first surface is greater than a length of each of the second set of electronic components extending from the second surface toward the first surface.

18. The electronic device of claim 16, further comprising:
at least one processor; and
memory, comprising one or more storage mediums, storing instructions,
wherein the first support member comprises a first electrode,
wherein the second support member comprises a second electrode configured to come into contact with the first electrode,
wherein the instructions, when being executed by the at least one processor individually or collectively, cause the electronic device to, based on the contact between the first electrode and the second electrode, identify that the first support member and the second support member are contacted with each other.

19. The electronic device of claim 18, wherein the instructions, when being executed by the at least one processor, cause the electronic device to:
supply power to at least one electronic component around the first support member and the second support member while the first support member is spaced apart from the second support member; and
bypass or cut off supplying power to the at least one electronic component in response to the contact between the first support member and the second support member identified through contact between the first electrode and the second electrode.

20. The electronic device of claim 19, wherein the instructions, when being executed by the at least one processor individually or collectively, further cause the electronic device to:
identify a contact time between the first support member and the second support member through contact between the first electrode and the second electrode, and
bypass supplying power supplied to the at least one electronic component around the first support member and the second support member in response to identifying the contact time less than a reference time, and
cut off the power supplied to the at least one electronic component in response to identifying the contact time equal to or greater than the reference time.
